(19) United States
(12) Patent Application Publication
(10) Pub. No.: US 2026/0173472 A1
(43) Pub. Date: Jun. 18, 2026

(54) METAL SILICIDE FOR CONTACT AND METHODS OF FORMING SAME

(71) Applicant: Taiwan Semiconductor Manufacturing Company, Ltd., Hsin-Chu (TW)

(72) Inventors: Chia-Hung Chu, Taipei City (TW); Olivia Pei-Hua Lee, Hsinchu County (TW); Hsin Wang, New Taipei City (TW); Hao-Chin Huang, Kaohsiung City (TW); Wei-Yip Loh, Hsinchu City (TW); Sung-Li Wang, Zhubei City (TW)

(21) Appl. No.: 19/190,384

(22) Filed: Apr. 25, 2025

Related U.S. Application Data
(60) Provisional application No. 63/734,625, filed on Dec. 16, 2024.

(51) Int. Cl. H10D 62/13; C23C 14/04; C23C 14/06; C23C 14/58; C23C 16/04; C23C 16/42; C23C 16/44; C23C 28/04; H10D 30/00; H10D 30/01; H10D 62/10; H10D 84/01; H10D 84/85

(52) U.S. Cl. CPC H10D 62/151; C23C 14/046; C23C 14/0682; C23C 14/5806; C23C 16/045; C23C 16/42; C23C 16/4408; C23C 28/04; H10D 30/0191; H10D 30/503; H10D 62/121; H10D 84/017; H10D 84/851

(57) ABSTRACT

A method includes providing a structure including a bottom source/drain feature, a bottom interlayer dielectric (ILD) layer disposed over the bottom source/drain feature, a top source/drain feature disposed over the bottom ILD layer and the bottom source/drain feature, and a top ILD layer disposed over the top source/drain feature. The method further includes forming a trench extending in the top ILD layer and the bottom ILD layer. The trench exposes a top surface and a sidewall of the top source/drain feature and a top surface of the bottom source/drain feature. The method further includes forming first silicide layers on the top surface and the sidewall of the top source/drain feature and the top surface of the bottom source/drain feature, forming second silicide layers on the first silicide layers, and forming a metal fill layer in the trench. The first silicide layers and the second silicide layers have different compositions.

### PRIORITY DATA

This application claims the benefit of U.S. Provisional Application No. 63/734,625 filed Dec. 16, 2024, the entirety of which is herein incorporated.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, stacked device structures are introduced to enable further density reduction for advanced IC technology nodes. However, fabrication of such stacked device structures introduces more challenges. As a result, existing implementations have not been satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor structure, according to one or more aspects of the present disclosure.

FIG. 2 illustrates a fragmentary top view of an exemplary semiconductor structure during various fabrication stages in the method of FIG. 1, according to one or more aspects of the present disclosure.

FIGS. 3, 4, 5, 6, 7, 8, 10, 11, 12A, 12B, 13A, 13B, 14, and 15 illustrate fragmentary cross-sectional views of an exemplary semiconductor structure during various fabrication stages in the method of FIG. 1, according to one or more aspects of the present disclosure.

FIGS. 9A-1, 9A-2, 9A-3, 9B-1, and 9B-2 illustrate fragmentary schematic cross-sectional views of an exemplary semiconductor structure during various fabrication stages in the method of FIG. 1, according to one or more aspects of the present disclosure.

FIG. 16 illustrates a flowchart of a method for forming a semiconductor structure, according to one or more aspects of the present disclosure.

FIGS. 17, 18, 19, 20, 21, 22, 23, 24, and 25 illustrate fragmentary cross-sectional views of an exemplary semiconductor structure during various fabrication stages in the method of FIG. 16, according to one or more aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Stacked transistor structures can provide further density reduction for advanced integrated circuit (IC) technology nodes (particularly as they advance to 3 nm (N3) and below), especially when the stacked transistor structures include multigate devices, such as fin-like field effect transistors (FinFETs), gate-all-around (GAA) transistors including nanowires and/or nanosheets, other types of multigate devices, etc. Stacked transistor structures include vertically stacked transistors. For example, a stacked transistor structure can include a first transistor (i.e., an upper/top transistor) disposed over a second transistor (i.e., a lower/bottom transistor). The transistor stack can provide a complementary field effect transistor (CFET) when the first transistor and the second transistor are of opposite conductivity type (i.e., an n-type transistor and a p-type transistor).

The stacked transistor structures may include source/drain contacts. In some cases, the stacked n-type and p-type transistors share a common source/drain (S/D) contact. The common S/D contact may be a local interconnect for connecting n-type and p-type source/drain (S/D) epitaxial features together. Since the n-type and p-type epitaxial features are stacked vertically one over the other, the local interconnect may need to penetrate through the top epitaxial feature until it lands on the bottom epitaxial feature. However, forming the source/drain contacts in stacked devices involve various challenges, such as higher resistance, high aspect ratio, poor metal fill. Therefore, although existing stacked device structures (e.g., CFET structures) and their related fabrication processes have been generally adequate for their intended purposes, they have not been entirely satisfactory in every aspect.

The present disclosure is generally related to stacked transistor structures having a source/drain contact. In an example process, a structure (e.g., a CFET) is provided. The structure includes a bottom transistor disposed over a substrate and a top transistor disposed over the bottom transistor. The bottom transistor includes a bottom source/drain feature and the top transistor includes a top source/drain feature vertically above the bottom source/drain feature. A trench is formed to expose the bottom source/drain feature and the top source/drain feature. A first silicide layer including a first metal is formed on exposed surfaces of the bottom source/drain feature and the top source/drain feature. A second silicide layer including a second metal is formed on the first silicide layer. Then a metal fill layer is formed in the trench and a planarization process is performed to remove excess materials, thereby forming the source/drain contact. The first silicide layer may be thicker on a horizontal surface (e.g., of the top source/drain feature) than on a vertical surface (e.g., of the top source/drain feature). The second silicide layer may be thinner on a horizontal surface (e.g., of the first silicide layer) than on a vertical surface (e.g., of the first silicide layer). By having the first silicide layer and the second silicide layer having different metals, dipole effect may be improved, which may reduce resistance of the source/drain contact. In addition, because of the smaller thickness of the first silicide layer on the vertical surface, a total thickness of the first silicide layer and the second silicide layer on the vertical surface is reduced, thus leaving more space for the metal fill layer and avoiding forming voids in the metal fill layer. In some other embodiments, instead of the first and second silicide layers, a third silicide layer is formed, and after forming the third silicide layer, a soak process and a post treatment are performed to remove metal residues on sidewalls of the trench. The metal fill layer is then formed in the trench. By removing the metal residues from sidewalls of the trench, filling the metal fill layer in the trench may be improved, reliability and integrity of the source/drain contact may be improved.

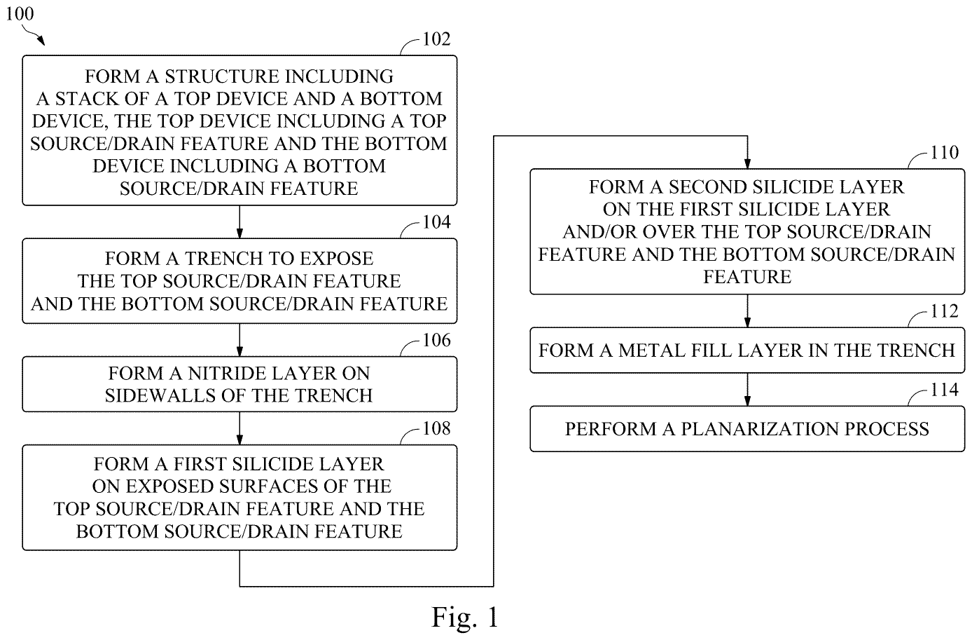

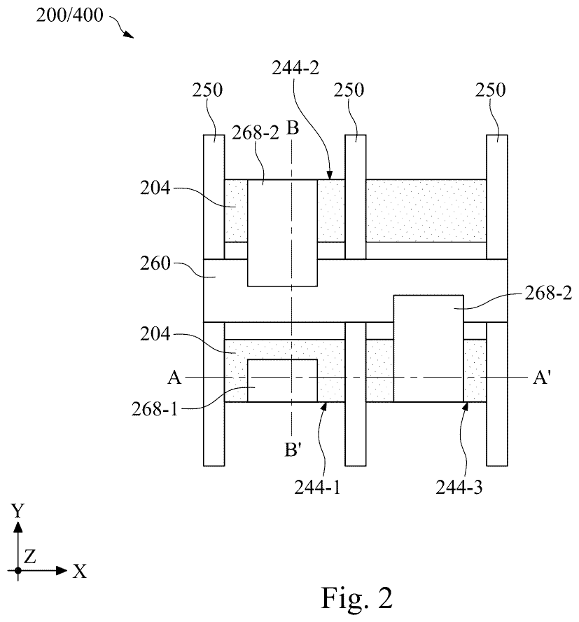

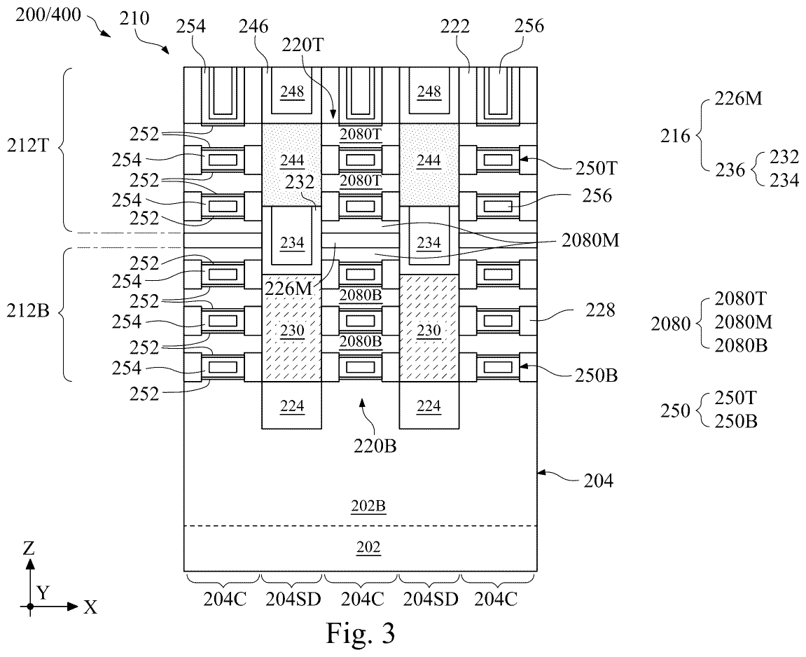

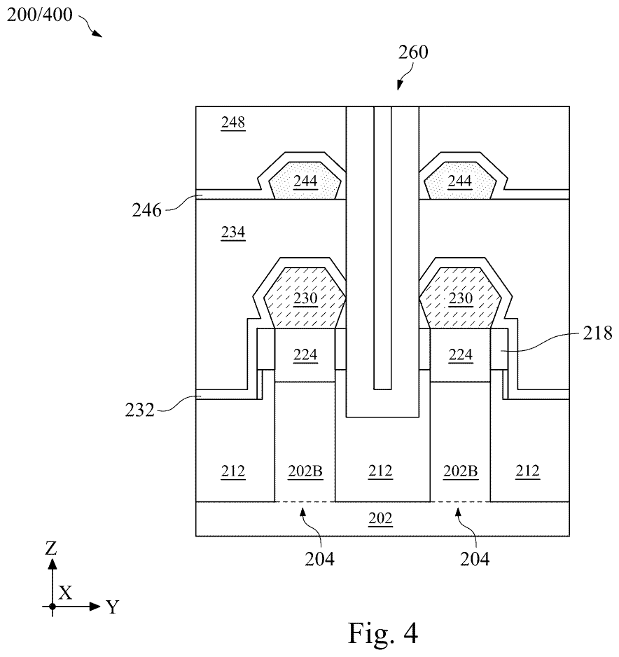

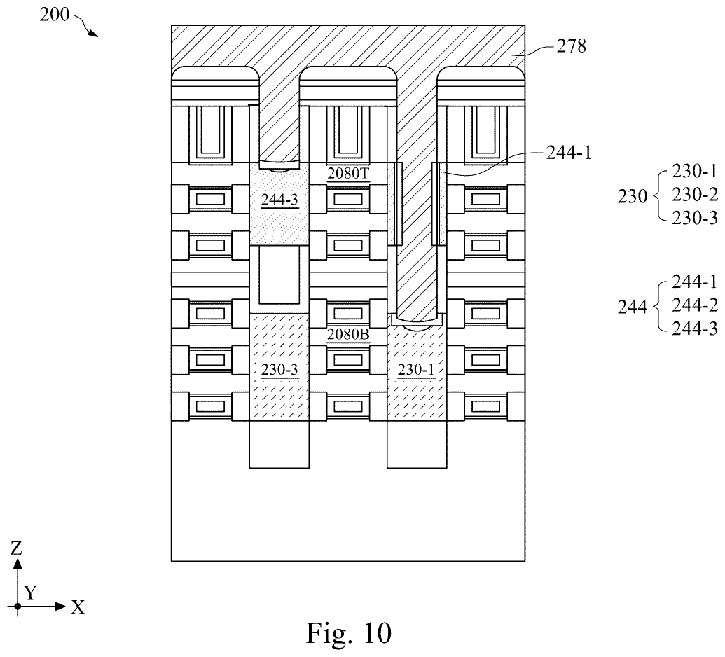

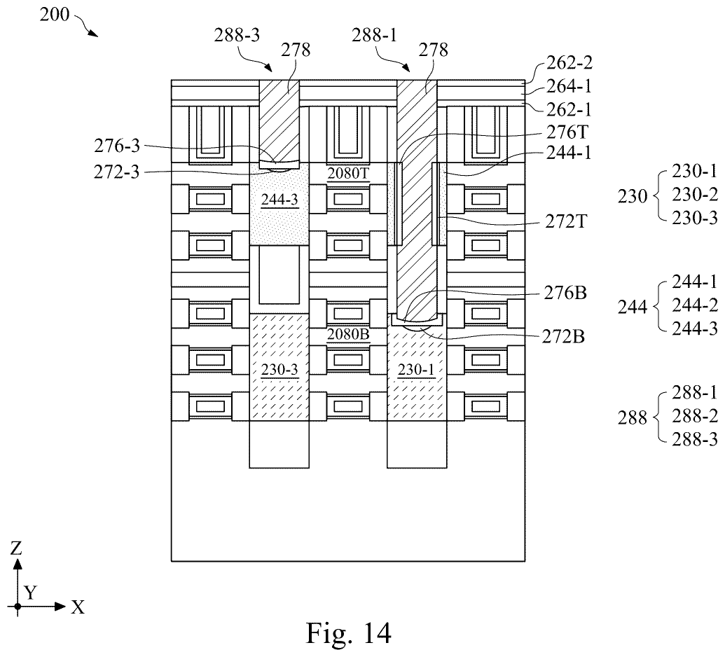

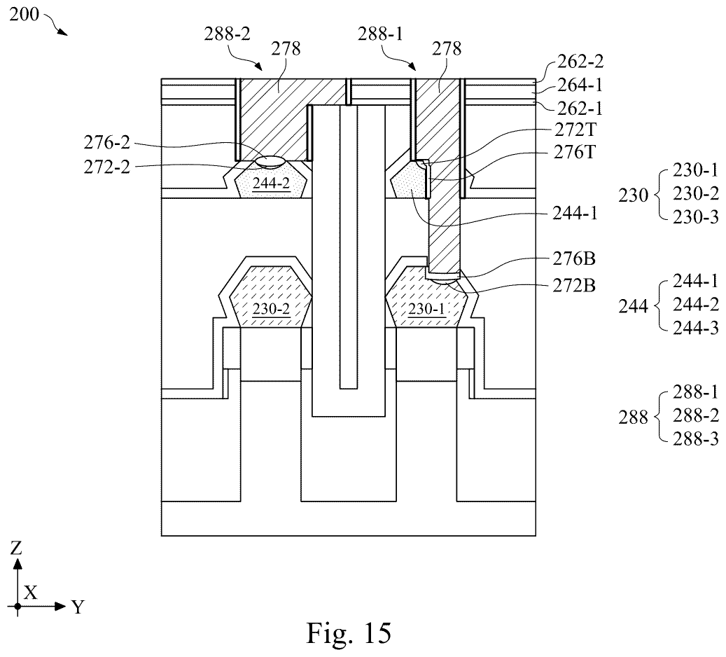

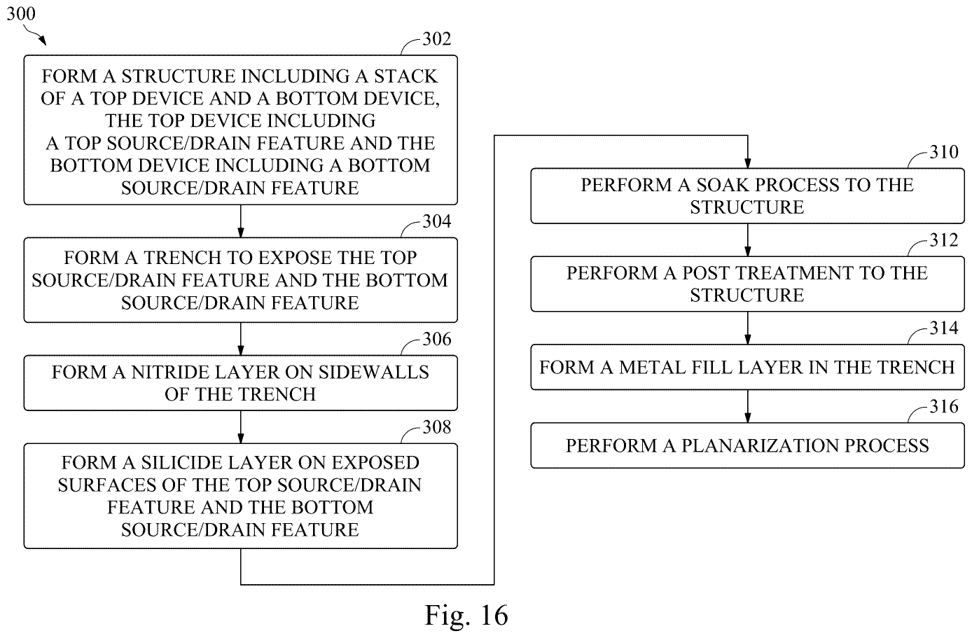

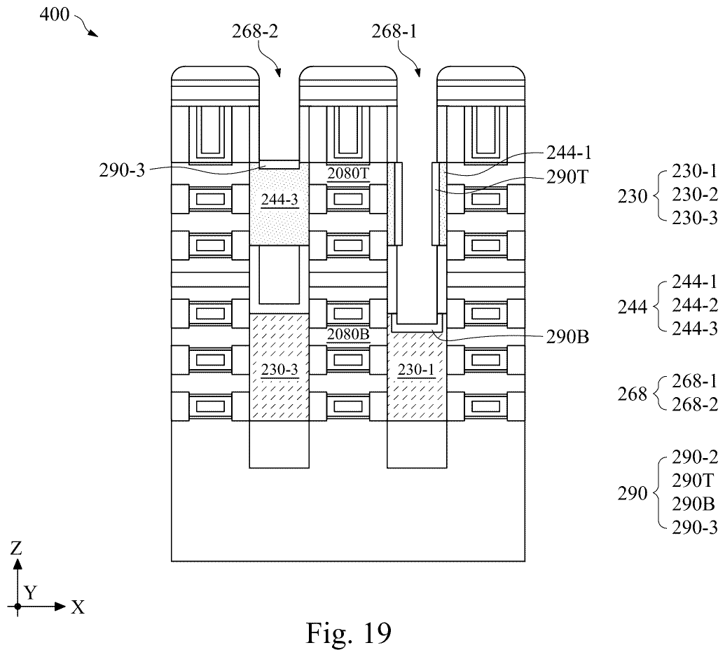

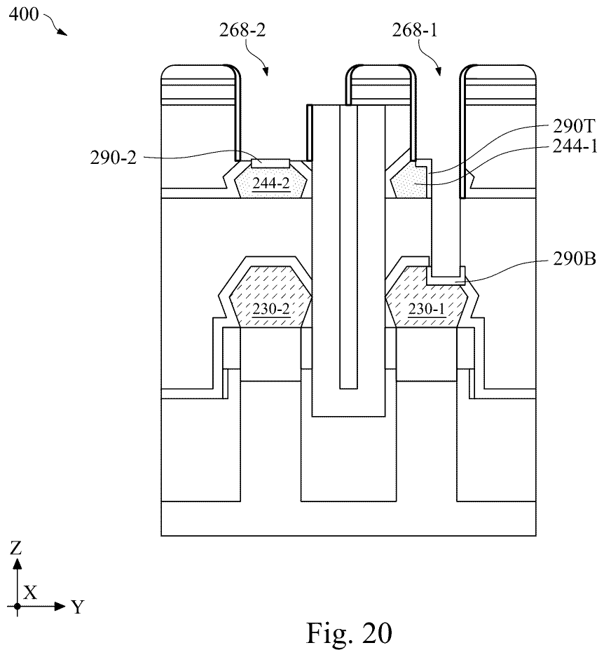

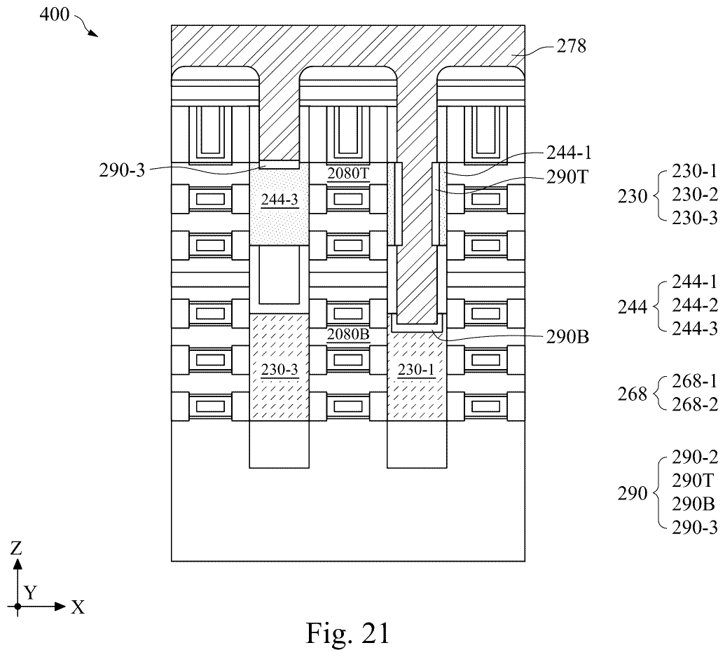

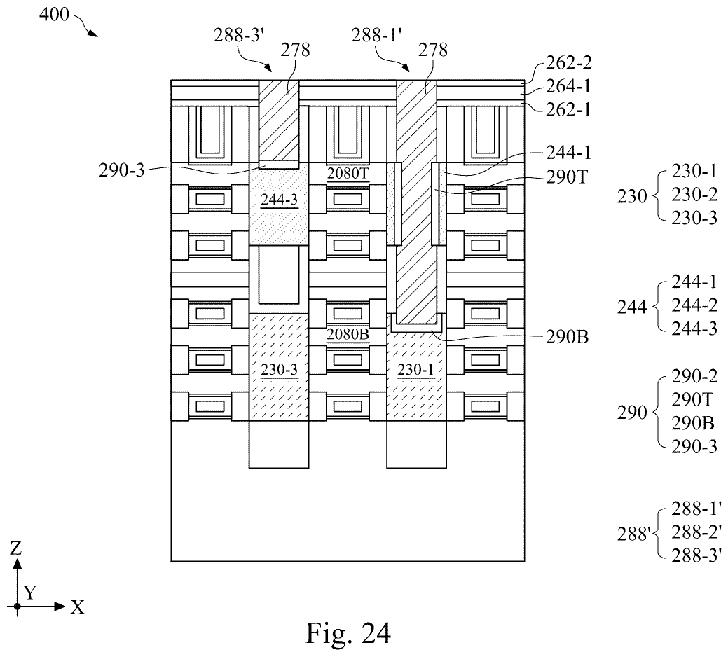

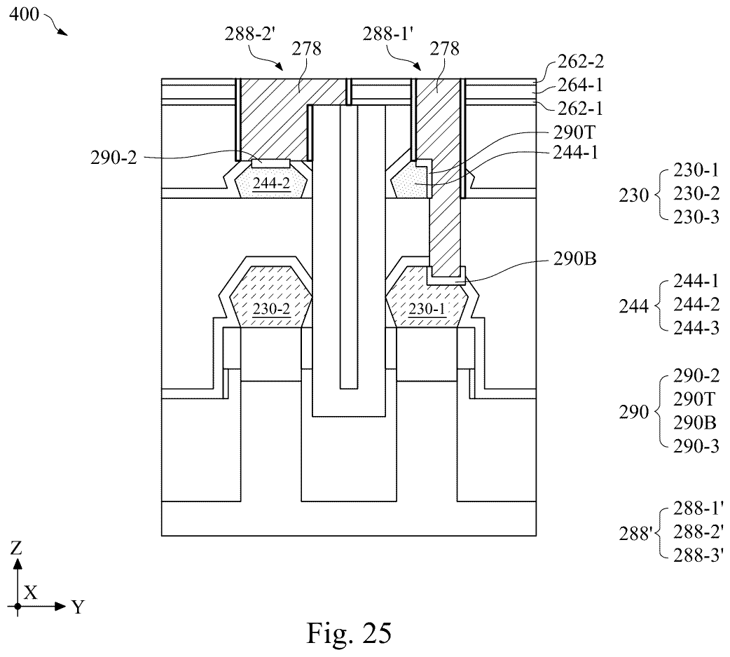

The various aspects of the present disclosure will now be described in more detail with reference to the figures. In that regard, FIG. 1 is a flowchart illustrating method 100 of forming a semiconductor structure according to embodiments of the present disclosure. Method 100 is described below in conjunction with FIGS. 2-15. FIGS. 2-8 and 10-15 are fragmentary top or cross-sectional views of a structure 200 at different stages of fabrication according to embodiments of method 100 in FIG. 1. FIGS. 9A-1 to 9B-2 are fragmentary schematic cross-sectional views of the structure 200 at different stages of fabrication according to embodiments of method 100 in FIG. 1. FIG. 16 is a flowchart illustrating method 300 of forming a semiconductor structure according to embodiments of the present disclosure. Method 300 is described below in conjunction with FIGS. 2 and 17-25, which are fragmentary top or cross-sectional views of a structure 400 at different stages of fabrication according to embodiments of method 300 in FIG. 16. FIGS. 3, 5, 7, 10, 14, 17, 19, 21, and 24 are fragmentary cross-sectional views taken along line A-A′ of FIG. 2, and FIGS. 4, 6, 8, 11-13B, 15, 18, 20, 22-23, and 25 are fragmentary cross-sectional views taken along line B-B′ of FIG. 2. Method 100 (or 300) is merely an example and is not intended to limit the present disclosure to what is explicitly illustrated in method 100 (or 300). Additional steps can be provided before, during and after method 100 (or 300), and some steps described can be replaced, eliminated, or moved around for additional embodiments of method 100 (or 300). Not all steps are described herein in detail for reasons of simplicity. Because the structure 200 (or 400) will be fabricated into a semiconductor structure, the structure 200 (or 400) may be referred to herein as a semiconductor structure 200 (or 400) or a semiconductor device 200 (or 400) as the context requires. For avoidance of doubts, the X, Y and Z directions in FIGS. 2-8, 10-15, and 17-25 are perpendicular to one another and are used consistently throughout the present disclosure. Throughout the present disclosure, like reference numerals denote like features unless otherwise excepted. That is, material properties and comparisons thereof for various numbered elements described in association with a method or a figure should apply to the same numbered elements described in association with a different method or a different figure.

Referring to FIGS. 1-4, method 100 includes a block 102 where a structure 200 is formed or provided. FIGS. 2-4 have been simplified for the sake of clarity to better understand the inventive concepts of the present disclosure. Additional features can be added in the structure 200, and some of the features described below can be replaced, modified, or eliminated in other embodiments of the structure 200.

Referring to FIG. 2, the structure 200 includes active regions 204 extending lengthwise along the X-direction and gate structures 250 extending lengthwise along the Y-direction. As will be described further below, the active region 204 includes a vertical stack of nanostructures (or channel members) stacked along the Z-direction.

Referring to FIGS. 3-4, the structure 200 includes a substrate 202 and various features (e.g., a stacked device structure 210) that have been fabricated on the substrate 202. The structure 200 includes a fin base structure 202B protruding from the substrate 202. Along the X-direction, the active region 204 includes channel regions 204C interleaved by source/drain regions 204SD. The stacked device structure 210 includes a device stack, such as a top device 212T vertically stacked over a bottom device 212B, disposed over the substrate 202. A n insulation structure 216 is disposed between and separates the device 212T and the device 212B. The insulation structure 216 may be a single layer/feature or a multilayer/feature structure, and in the depicted embodiment, includes an insulation structure 226M and an insulation structure 236. In the depicted embodiment, the stacked device structure 210 is fabricated monolithically, and thus can be referred to as a monolithic stacked device structure 210. In some embodiments, the stacked device structure 210 is fabricated sequentially, and thus can be referred to as a sequential stacked device structure 210.

The device 212T and the device 212B each include at least one electrically functional device, such as a top transistor 220T and a bottom transistor 220B, respectively. The stacked device structure 210 thus includes a transistor stack having a top transistor (e.g., the transistor 220T) and a bottom transistor (e.g., the transistor 220B) separated and/or electrically isolated from one another by the isolation structure 216. In some embodiments, the transistor 220B and the transistor 220T are transistors of an opposite conductivity type. For example, the transistor 220B is a p-type transistor, and the transistor 220T is an n-type transistor, or vice versa. In such embodiments, the transistor 220B and the transistor 220T form a CFET. In some embodiments, the transistor 220B and the transistor 220T are transistors of a same conductivity type. For example, the transistor 220B and the transistor 220T are both n-type transistors or both p-type transistors.

The device 212T includes various features and/or components, such as semiconductor layers 2080T, semiconductor layers 2080M, gate spacers 222, inner spacers 228, source/drain features 244 (also referred to as top source/drain features 244), a contact etch stop layer (CESL) 246, an interlayer dielectric (ILD) layer 248, and a gate structure segment 250T. The device 212B also includes various features and/or components, such as a fin base structure 202B, semiconductor layers 2080B, semiconductor layers 2080M, isolation features 212, inner spacers 228, source/drain features 230 (also referred to as bottom source/drain features 230), base epitaxial regions 224, a CESL 232, an ILD layer 234, and a gate structure segment 250B. The gate structure segment 250T and the gate structure segment 250B are collectively referred to as the gate structure 250 of the stacked device structure 210, such as a metal gate or a high-k/metal gate of a CFET. The semiconductor layers 2080B, 2080M, and 2080T may be individually or collectively referred to as semiconductor layer(s) 2080 as the context requires.

In the depicted embodiment, the transistor 220B is a GAA transistor. For example, the transistor 220B has two channels provided by the semiconductor layers 2080B (also referred to as channel layers), which are suspended over the substrate 202 and extend between respective source/drain features (e.g., the source/drain features 230). In some embodiments, the transistor 220B includes more or less channels (and thus more or less semiconductor layers 2080B). The transistor 220B further has the gate structure segment 250B disposed over its semiconductor layers 2080B and between its source/drain features 230, and the inner spacers 228 are disposed between its gate structure segment 250B and its source/drain features 230. A long a gate widthwise direction (e.g., in an X-Z plane), the gate structure segment 250B is over the top semiconductor layer 2080B, between the semiconductor layers 2080B, and between the bottom semiconductor layer 2080B and the fin base structure 202B. Along a gate lengthwise direction (e.g., in a Y-Z plane), the gate structure segment 250B wraps around the semiconductor layers 2080B. During operation of the GAA transistor, current can flow through the semiconductor layers 2080B and between the source/drain features 230. The semiconductor layers 2080M are suspended over substrate 202 and extend between respective insulation structures 236, and the insulation structures 226M are disposed between the semiconductor layer 2080M of the device 212B and the semiconductor layer 2080M of the device 212T.

In the depicted embodiment, the transistor 220T is also a GAA transistor. For example, the transistor 220T has two channels provided by the semiconductor layers 2080T (also referred to as channel layers), which are suspended over the substrate 202 and extend between respective source/drain features (e.g., the source/drain features 244). In some embodiments, the transistor 220T includes more or less channels (and thus more or less semiconductor layers 2080T). The transistor 220T further has the gate structure segment 250T disposed over its semiconductor layers 2080T and between its source/drain features 244, the gate structure segment 250T disposed between respective gate spacers 222, and the inner spacers 228 disposed between its gate structure segment 250T and its source/drain features 244. Along a gate widthwise direction, the gate structure segment 250T is over the top semiconductor layer 2080T, between the semiconductor layers 2080T, and between the bottom semiconductor layer 2080T and the semiconductor layer 2080M. Along a gate lengthwise direction, the gate structure segment 250T wraps around the semiconductor layers 2080T. During operation of the GAA transistor, current can flow through the semiconductor layers 2080T and between the source/drain features 244.

The substrate 202, the fin base structure 202B, and the semiconductor layers 2080 include an elementary semiconductor, such as silicon and/or germanium; a compound semiconductor, such as silicon carbide, gallium arsenide, gallium phosphide, indium phosphide, indium arsenide, indium antimonide, or a combination thereof; an alloy semiconductor, such as SiGe, GaAsP, AlInAs, AlGaAs, GaInAs, GaInP, GaInAsP, or a combination thereof; or a combination thereof. In the depicted embodiment, the substrate 202, the fin base structure 202B, and the semiconductor layers 2080 include silicon. In some embodiments, the top semiconductor layers 2080T and the bottom semiconductor layers 2080B include different semiconductor materials, such as silicon and silicon germanium, respectively, or vice versa. In some embodiments, the substrate 202 is a semiconductor-on-insulator substrate, such as a silicon-on-insulator substrate, a silicon germanium-on-insulator substrate, or a germanium-on-insulator substrate. The substrate 202 and the fin base structure 202B may include various doped regions, such as p-wells and n-wells. The n-wells are doped with n-type dopants, such as phosphorus, arsenic, other n-type dopant, or a combination thereof. The p-wells are doped with p-type dopants, such as boron, indium, other p-type dopant, or a combination thereof.

The isolation features 212 electrically isolate active device regions and/or passive device regions. For example, the isolation features 212 separate and electrically isolate the fin base structures 202B from each other and/or other device regions/features. The isolation features 212 include silicon oxide, silicon nitride, silicon oxynitride, other suitable isolation material (for example, including silicon, oxygen, nitrogen, carbon, etc.), or a combination thereof. The isolation features 212 may have a multilayer structure. For example, the isolation features 212 include a bulk dielectric (e.g., an oxide layer) over a dielectric liner (for example, silicon nitride, silicon oxide, silicon oxynitride, silicon oxycarbonitride, or a combination thereof). In another example, the isolation features 212 include a bulk dielectric over a doped liner, such as a boron silicate glass (BSG) liner and/or a phosphosilicate glass (PSG) liner. Dimensions and/or characteristics of the isolation features 212 are configured to provide shallow trench isolation (STI) structures, deep trench isolation (DTI) structures, local oxidation of silicon (LOCOS) structures, other suitable isolation structures, or a combination thereof. In the depicted embodiment, the isolation features 212 may be ST Is.

The gate spacers 222 are disposed along sidewalls of upper portions of the gate structure segment 250T, the inner spacers 228 are disposed under the gate spacers 222 along sidewalls of the gate structure segment 250T and/or gate structure segment 250B, and fin spacers 218 are disposed along sidewalls of the base epitaxial regions 224. The inner spacers 228 are between the semiconductor layers 2080B and 2080T and between the bottom semiconductor layers 2080B and the fin base structures 202B. The gate spacers 222, the inner spacers 228, and the fin spacers 218 include a dielectric material, which may include silicon, oxygen, carbon, nitrogen, other suitable dielectric constituent, or a combination thereof (e.g., silicon oxide, silicon nitride, silicon oxynitride, silicon carbide, silicon carbonitride, silicon oxycarbide, silicon oxycarbonitride, or a combination thereof). The gate spacers 222, the inner spacers 228, and the fin spacers 224 may include different materials and/or different configurations (e.g., different numbers of layers). In some embodiments, the gate spacers 222, the inner spacers 228, the fin spacers 218, or a combination thereof have a multilayer structure. In some embodiments, the gate spacers 222 and/or the fin spacers 218 include more than one set of spacers, such as seal spacers, offset spacers, sacrificial spacers, dummy spacers, main spacers, or a combination thereof. The various sets of spacers may have different compositions.

The bottom source/drain features 230 and the top source/drain features 244 have the same or different compositions and/or materials depending on configurations of their respective transistors. The bottom source/drain features 230 and the top source/drain features 244 may be doped with n-type dopants and/or p-type dopants. In some embodiments, the bottom source/drain features 230 and/or the top source/drain features 244 include silicon that may be doped with carbon, phosphorous, arsenic, other n-type dopant, or a combination thereof (e.g., Si:C epitaxial source/drains, Si:P epitaxial source/drains, or Si:C:P epitaxial source/drains). In some embodiments, the bottom source/drain features 230 and/or the top source/drain features 244 include silicon germanium or germanium, which may be doped with boron, other p-type dopant, or a combination thereof (e.g., Si:Ge:B epitaxial source/drains). In some embodiments, the bottom source/drain features 230 and the top source/drain features 244 are of opposite conductivity types (e.g., n-type and p-type). In some embodiments, the bottom source/drain features 230 are p-type source/drain features, for example, including silicon germanium doped with boron, and the top source/drain features 244 are n-type source/drain features, for example, including silicon doped with phosphorous. In some embodiments, the bottom source/drain features 230 and/or the top source/drain features 244 include more than one epitaxial semiconductor layer, where the epitaxial semiconductor layers may include the same or different materials and/or the same or different dopant concentrations. In some embodiments, the bottom source/drain features 230 and/or the top source/drain features 244 include materials and/or dopants that achieve desired tensile stress and/or compressive stress in adjacent channel regions (e.g., formed by the semiconductor layers 2080T and the semiconductor layers 2080B). As used herein, source/drain region, source/drain feature, epitaxial source/drain, epitaxial source/drain feature, etc. may refer to a source of a device, a drain of a device, or a source and/or a drain of multiple devices.

The base epitaxial regions 224 may be disposed below the bottom source/drain features 230. The epitaxial regions 224 function to reduce leakage into the substrate 202. The base epitaxial regions 224 may include undoped semiconductor material. In the depicted embodiments, the base epitaxial regions 224 include undoped silicon (Si), undoped silicon germanium (SiGe), or undoped germanium (Ge). The base epitaxial regions 224 may be deposited using vapor-phase epitaxy (VPE), ultra-high vacuum chemical vapor deposition (UHV-CVD), molecular beam epitaxy (MBE), and/or other suitable epitaxy deposition processes. A top surface of the base epitaxial regions 224 may be at a same level as a top surface of the fin base structure 202B.

The ILD layer 248 and the ILD layer 234 include a dielectric material including, for example, silicon oxide, carbon doped silicon oxide, silicon nitride, silicon oxynitride, tetraethyl orthosilicate (TEOS)-formed oxide, BSG, PSG, borophosphosilicate glass (BPSG), fluorosilicate glass (FSG), xerogel, aerogel, amorphous fluorinated carbon, parylene, benzocyclobutene-based (BCB) dielectric material, polyimide, other suitable dielectric material, or a combination thereof. In some embodiments, the ILD layer 248 and/or the ILD layer 234 include a dielectric material having a dielectric constant that is less than a dielectric constant of silicon dioxide. The CESL 232 and the CESL 246 include a material different than a material of the ILD layer 234 and the ILD layer 248, respectively. In some embodiments, CESL 232 and the CESL 246 include silicon nitride and the ILD layer 234 and the ILD layer 248 include silicon oxide. The ILD layer 234, the ILD layer 248, the CESL 232, the CESL 246, or a combination thereof may include a multilayer structure. The ILD layer 234, the ILD layer 248, the CESL 232, and the CESL 246 may be collectively referred to as a dielectric structure.

In some embodiments, the insulation structure 226M includes a dielectric material, which may include silicon, oxygen, carbon, nitrogen, other suitable dielectric constituent, or a combination thereof (e.g., silicon oxide, silicon nitride, silicon oxynitride, silicon carbide, silicon carbonitride, silicon oxycarbide, silicon oxycarbonitride, or a combination thereof). In furtherance of the depicted embodiment, the source/drain features 244 are separated and/or electrically isolated from the source/drain features 230 by the insulation structure 236. In some embodiments, the insulation structure 236 may be formed by a portion of the CESL 232 and the ILD layer 234.

The gate structure 250 may include an interfacial layer 252 interfacing the semiconductor layers 2080 and the fin base structure 202B in the channel region 204C, a gate dielectric layer 254 over the interfacial layer 252, and a gate electrode 256 over the gate dielectric layer 254. The interfacial layer 252 may include a dielectric material, such as SiO₂, SiGeOₓ, HfSiO, SiON, other dielectric material, or a combination thereof. In some embodiments, the gate dielectric layer 254 includes a high-k dielectric layer. The high-k dielectric layer includes a high-k dielectric material, which generally refers to dielectric materials having a dielectric constant that is greater than a dielectric constant of silicon dioxide (k≈3.9), such as HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TiO, TiO₂, LaO, LaSiO, LaO₃, La₂O₃, Ta₂O₃, Ta₂O₅, Y₂O₃, SrTiO₃, BaZrO, BaTiO₃(BTO), (Ba,Sr)TiO₃ (BST), Si₃N₄, HfO₂—Al₂O₃, other high-k dielectric material, or a combination thereof. For example, the gate dielectric layer 254 includes a hafnium-based oxide (e.g., HfO₂) layer and/or a zirconium-based oxide (e.g., ZrO₂) layer. In some embodiments, the interfacial layer 252 and/or the gate dielectric layer 254 have a multilayer structure.

The gate electrode 256 may be disposed over the gate dielectric layer 254. The gate electrode 256 includes at least one electrically conductive gate layer. The electrically conductive gate layer includes an electrically conductive material, such as Al, Cu, Ti, Ta, W, Mo, Co, TaN, NiSi, CoSi, TiN, WN, TiAl, TiAlN, TaCN, TaC, TaSiN, other electrically conductive material, or a combination thereof. In some embodiments, the gate electrode 256 includes a work function layer. The work function layer is a conductive layer tuned to have a desired work function, such as an n-type work function or a p-type work function, for an n-type transistor or a p-type transistor, respectively. The work function layer includes work function metal(s) and/or alloys thereof, such as Ti, Ta, Al, Ag, Mn, Zr, W, Ru, Mo, TiC, TiAl, TiAlC, TiAlSiC, TaC, TaCN, TaSiN, TiSiN, TiN, TaN, TaSN, WN, WCN, ZrSi₂, MoSi₂, TaSi₂, NiSi₂, TaAl, TaAlC, TaSiAlC, TiAlN, or a combination thereof. In some embodiments, the gate electrode 256 includes a bulk layer over the gate dielectric layer 254 and/or the work function layer. The bulk layer includes a suitable conductive material, such as Al, W, Cu, Ti, Ta, TiN, TaN, polysilicon, other suitable metal(s) and/or alloys thereof, or a combination thereof. In some embodiments, the gate electrode 256 includes a barrier (blocking) layer over the work function layer and/or the gate dielectric layer 254. The barrier layer includes a material that prevents or eliminates diffusion and/or reaction of constituents between adjacent layers and/or promotes adhesion between adjacent layers, such as between the work function layer and the bulk layer. In some embodiments, the barrier layer includes metal and nitrogen, such as titanium nitride, tantalum nitride, tungsten nitride (e.g., W₂N), titanium silicon nitride (TiSiN), tantalum silicon nitride (TaSiN), other suitable metal nitride, or a combination thereof.

In some embodiments, referring to FIGS. 2 and 4, the structure 200 includes a gate isolation structure 260. The gate isolation structure 260 may extend lengthwise along the X-direction in the top view. In the depicted embodiment, the gate isolation structure 260 is disposed between two active regions 204. The gate isolation structure 260 may separate the gate structure 250 into two portions and electrically isolate the two portions. In some embodiments, the gate isolation structure 260 includes silicon nitride, silicon oxide, silicon oxynitride, silicon oxycarbonitride, silicon oxycarbide, silicon carbonitride, or a combination thereof. In one embodiment, the gate isolation structure 260 includes a silicon nitride liner and a dielectric fill surrounded by the silicon nitride liner.

Referring to FIGS. 1 and 5-6, method 100 includes a block 104 where trenches 268 are formed to expose the top source/drain features 244 and the bottom source/drain features 230.

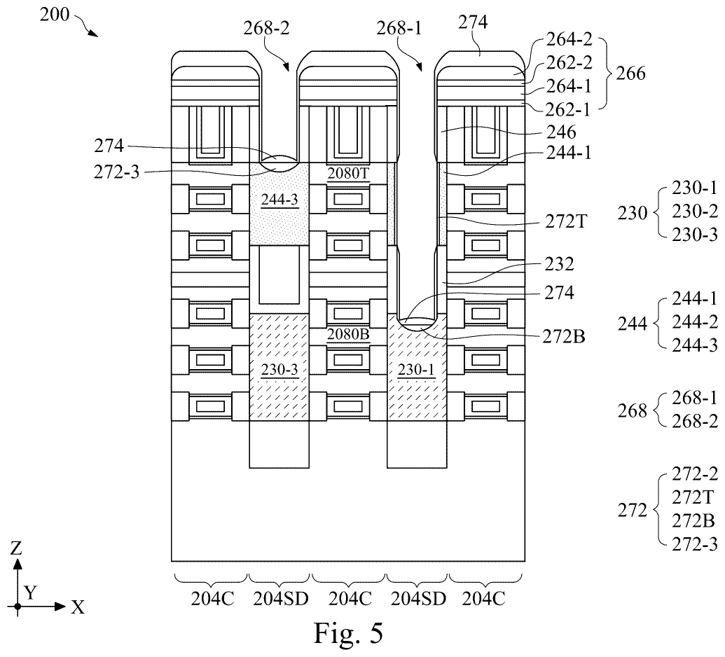

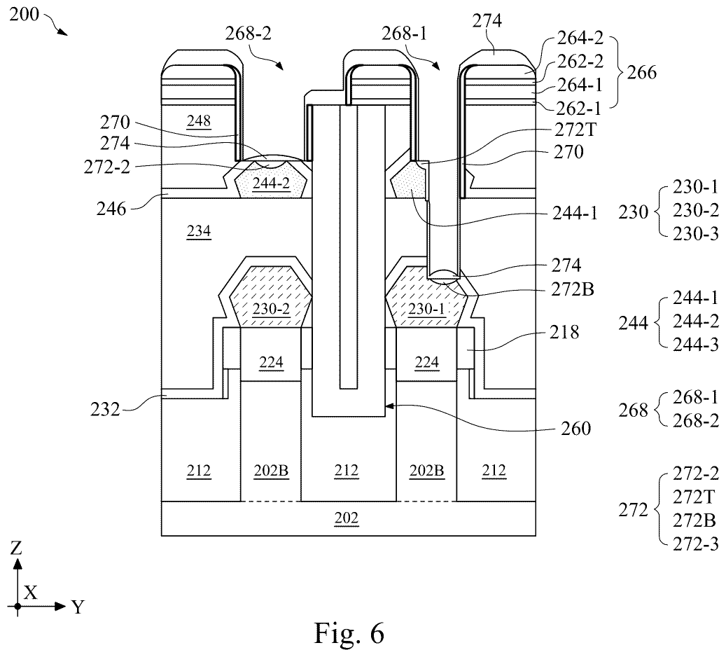

The trenches 268 may include a first type trench 268-1 and a second type trench 268-2. The first type trench 268-1 vertically extends through the ILD layers 248 and 234 and the CESL 246 and 232 to expose both the top source/drain feature 244 and the bottom source/drain feature 230. A top surface and a sidewall of the top source/drain feature 244 (e.g., at least two facets thereof), and a top surface of the bottom source/drain feature 230 are exposed in the first type trench 268-1. Thus, the first type trench 268-1 has a first depth to the top surface of the top source/drain feature 244 and a second depth to the top surface of the bottom source/drain feature 230. The second type trench 268-2 extends through the ILD layer 248 and the CESL 246 to expose only the top source/drain feature. The second type trenches 268-2 in FIGS. 5 and 6 may be configured the same or differently. For clarity, the top source/drain feature 244 and the bottom source/drain feature 230 exposed in the first type trench 268-1 are referred to as a top source/drain feature 244-1 and a bottom source/drain feature 230-1, respectively. The top source/drain feature 244 exposed in the second type trench 268-2 in FIG. 6 and the bottom source/drain feature 230 thereunder are referred to as a top source/drain feature 244-2 and a bottom source/drain feature 230-2, respectively. The top source/drain feature 244 exposed in the second type trench 268-2 in FIG. 5 and the bottom source/drain feature 230 thereunder are referred to as a top source/drain feature 244-3 and a bottom source/drain feature 230-3, respectively.

In some embodiments, patterning processes are performed to dielectric layers (e.g., the ILD layers 248 and 234 and the CESL 246 and 232) to form the trenches 268. In some embodiments, a portion of the top source/drain feature 230 is removed in the patterning processes. The first type trenches 268-1 and the second type trenches 268-2 may be formed in different patterning processes. Forming the first type trench 268-1 may include more than one patterning processes to extend the first type trench 268-1 to the first depth and the second depth.

The patterning processes may include a plurality of lithography processes and etching processes. The lithography process may include forming a patterned mask layer (e.g., a patterned mask layer 266) over the ILD layer 248. The patterned mask layer 266 may include multiple dielectric layers, such as an etch stop layer (ESL) 262-1, an ILD layer 264-1, an ESL 262-2, and an ILD layer 264-2 stacked one over another as depicted. The patterned mask layer 266 has openings therein, each of which overlaps a portion of a respective source/drain region 204SD in a top view. The etching process may include transferring a pattern in patterned mask layer 266 to the dielectric layers therebelow and/or the source/drain features 244/230, for example, by removing portions of the ILD layers 248 and 234, the CESL 246 and 232, and/or the source/drain features 244/230 exposed by the openings. The etching process may include a dry etch, a wet etch, other suitable etching process, or a combination thereof.

Still referring to FIGS. 1 and 5-6, method 100 includes a block 106 where a dielectric liner 270 is formed on sidewalls of the trenches 268.

The dielectric liner 270 may include a dielectric material such as silicon oxide, silicon nitride, silicon carbide, silicon oxynitride, SiCN films, silicon oxycarbide, SiOCN films, and/or combinations thereof. In some embodiments, the dielectric liner 270 includes silicon nitride. By way of example, the dielectric liner 270 may be formed by blanket depositing a dielectric material layer in a conformal manner over the structure 200 using processes such as, a chemical vapor deposition (CVD) process, a subatmospheric CVD (SACVD) process, an atomic layer deposition (ALD) process, a physical vapor deposition (PVD) process, or other suitable process. In the illustrated embodiment, the deposition of the dielectric material layer is followed by an etching-back (e.g., anisotropically) process to remove the dielectric material layer from horizontal surface(s) and a bottom portion of sidewall surface(s) of the trenches 268. In some embodiments, the etching-back process may include a wet etch process, a dry etch process, a multiple-step etch process, and/or a combination thereof. In some embodiments, the etching-back process includes a directional etching process (e.g., a tilted plasma etching), in which an ion beam may be directed to a surface of structure 200 with a tilt angle with respect to the Z-direction. In embodiments, bottom portions of sidewalls of the trenches 268 below the top source/drain feature 244-1 are exposed after the etching-back process. The dielectric material layer may remain on exposed sidewalls of the ILD layer 248, the CESL 246, and the gate isolation structure 260 as the dielectric liner 270. The dielectric liner 270 prevents diffusion between the metal fill layer (to be described below) and the dielectric layers (e.g., the ILD layer 248, the CESL 246). In some embodiments, the deposited dielectric liner 270 is first treated such that its composition is changed. In this case, the treated portion of the dielectric liner 270 remains during the etching-back process and the untreated portion is removed by the etching-back process. In furtherance of the embodiments, the dielectric liner 270 includes silicon oxide, and the treating process includes a tilted ion implantation using proper ions, such as nitrogen ions so that nitrogen is introduced into a bottom portion of the dielectric liner 270. Thereafter, the treated portion of the dielectric liner 270 is selectively removed by the etching-back process using a proper etchant such as phosphorous acid.

Still referring to FIGS. 1 and 5-6, method 100 includes a block 108 where a first silicide layer is formed on exposed surfaces of the source/drain features 230-1, 244-1, 244-2, and 244-3. Before forming the first silicide layer, a cleaning process may be performed to remove any debris from the surfaces in the trenches 268. In some embodiments, the cleaning process includes purging a carrier gas (e.g., an inert gas) to clean the surfaces of the structure 200.

In FIGS. 5 and 6, the first silicide layers 272 may include first silicide layers 272-3, 272-2, 272T, and 272B disposed on the source/drain features 244-3, 244-2, 244-1, and 230-1, respectively. The first silicide layers 272-3, 272-2, 272T, and 272B may be collectively or individually referred to as the first silicide layer(s) 272 as the context requires. Forming the first silicide layers 272 may include depositing a first metal layer 274 to the structure 200 (including exposed surfaces of the source/drain features 230 and 244 in the trenches 268) and performing a first thermal process (e.g., an annealing process) to the structure 200 to cause constituents of the source/drains features 230 and 244 to react with metal constituents in the first metal layer 274.

Depositing the first metal layer 274 over the exposed surfaces of the source/drain features 230 and 244 in the trenches 268 may be by a suitable deposition process, such as a PVD process. The first thermal process may be at a first temperature greater than about 400 degree C., for example, at about 400 to about 500 degree C. In some embodiments, the first thermal process consumes and converts portions of the source/drain features 244-3, 244-2, 244-1, and 230-1 into the first silicide layers 272-3, 272-2, 272T, and 272B, respectively. The first metal layer 274 may include any metal constituent suitable for promoting silicide formation, such as zirconium, nickel, platinum, palladium, vanadium, titanium, cobalt, tantalum, ytterbium, other suitable metal, or a combination thereof. When the source/drain feature(s) are of n-type, the metal constituent may include Ti, Zr, Hf, Sc, Y, Yb, La, Er, Dy, Ce, or a combination thereof. When the source/drain feature(s) are of p-type, the metal constituent may include Al, W, Mo, Co, Ru, Re, Rh, Ir, Pt, Ni, Pd, Nb, V, or a combination thereof. The metal constituent may be chosen according to the conductivity type (or type, e.g., p-type or n-type) of the source/drain feature(s) 244 or the source/drain feature(s) 230. In some embodiments, the metal constituent is chosen according to the conductivity type of the respective source/drain feature 244. For example, the source/drain feature(s) 244 are of n-type and the metal constituent of the first silicide layer includes Ti, Zr, Hf, Sc, Y, Yb, La, Er, Dy, Ce, or a combination thereof. The first silicide layers 272 thus include a metal constituent and a constituent of the source/drain features 244-3, 244-2, 244-1, and 230-1 (for example, silicon and/or germanium). In some embodiments, the first metal layer 274 is a zirconium-containing layer, and first silicide layers 272 include zirconium and silicon and can be referred to as zirconium silicide layers. In the PVD process, deposition direction may be controlled, such that the first metal layer 274 may be selectively deposited more over horizontal surfaces (e.g., top surfaces) than over vertical surfaces (e.g., sidewalls). Thus, a thickness of the first metal layer 274 over horizontal surfaces is greater than that over vertical surfaces. A thickness of the first metal layer 274 over the sidewalls of the trenches 268 may be less than about 3 nm. Any un-reacted metal, such as remaining portions of the first metal layer 274, is selectively removed by any suitable process.

Referring to FIGS. 1 and 7-8, method 100 includes a block 110 where second silicide layers 276 are formed over the first silicide layers 272.

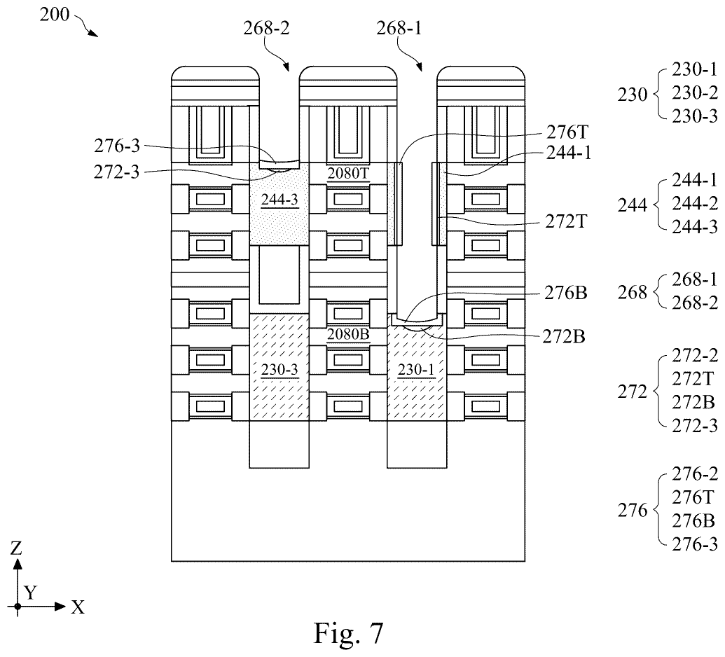

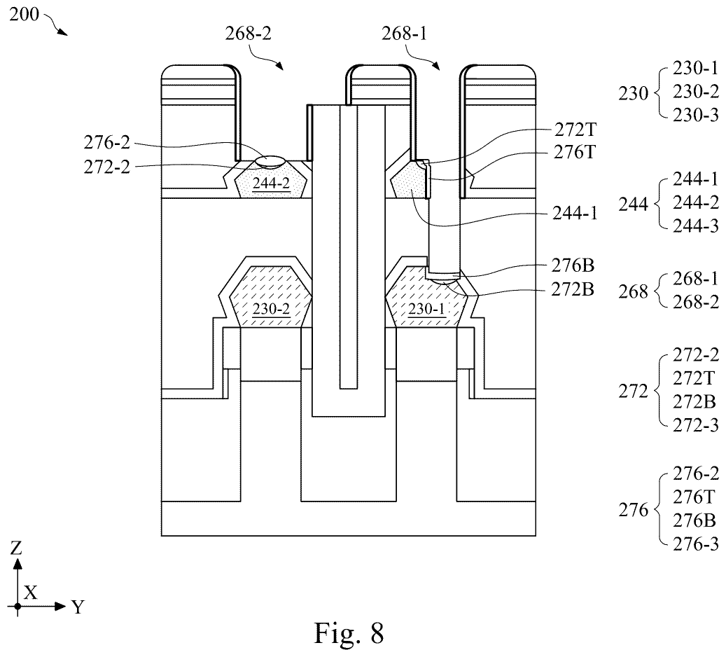

In FIGS. 7-8, the second silicide layers 276 may include second silicide layers 276-3, 276-2, 276T, and 276B disposed on the first silicide layers 272-3, 272-2, 272T, and 272B, respectively. The second silicide layers 276-3, 276-2, 276T, and 276B may be collectively or individually referred to as the second silicide layer(s) 276 as the context requires. Forming the second silicide layers 276 may include depositing a second metal layer (not depicted) to the structure 200 (including the first silicide layers 272) at a second temperature of about 350 degree C. to about 450 degree C. to cause constituents of the source/drains features 230 and 244 to diffuse through the first silicide layers 272 and react with metal constituents in the second metal layer. Any un-reacted metal, such as remaining portions of the second metal layer, is selectively removed by any suitable process. Removing the remaining portions of the second metal layer may also remove a portion of the first silicide layers 272 and the source/drain features 230 and/or 240 at the bottom of the trenches 268, thus exposing side portions of the source/drain features 244-3, 230-1, and 244-2.

Depositing the second metal layer may be by a suitable deposition process, such as a CVD process, a plasma enhanced CVD process. In some embodiments, constituents (e.g., silicon) of the source/drain features 244-3, 244-2, 244-1, and 230-1 diffuse through the first silicide layers 272-3, 272-2, 272T, and 272B, respectively, and react with the metal constituents in the second metal layer, thereby forming the second silicide layers 276-3, 276-2, 276T, and 276B, respectively. In the embodiments where side portions of the surfaces of the source/drain features 244-3, 244-2, and 230-1 are exposed, the constituents of the source/drain features 244-3, 244-2, and 230-1 at the portions of the surfaces may react with the second metal layer, to form a portion of the second silicide layers 276. The second metal layer may include any metal constituent suitable for promoting silicide formation, such as titanium (Ti), zirconium (Zr), nickel (Ni), platinum (Pt), palladium (Pd), vanadium (V), cobalt (Co), tantalum (Ta), ytterbium (Yb), other suitable metal, or a combination thereof. When the source/drain feature(s) are of n-type, the metal constituent may include Ti, Zr, hafnium (Hf), scandium (Sc), yttrium (Y), Yb, lanthanum (La), erbium (Er), dysprosium (Dy), cerium (Ce), or a combination thereof. When the source/drain feature(s) are of p-type, the metal constituent may include aluminum (AI), tungsten (W), molybdenum (Mo), Co, ruthenium (Ru), rhenium (Re), rhodium (Rh), iridium (Ir), Pt, Ni, Pd, niobium (Nb), V, or a combination thereof. The second silicide layers 276 thus include a metal constituent and a constituent of the source/drain features 244 or 230 (for example, silicon and/or germanium). In some embodiments, the second metal layer is a titanium-containing layer, and the second silicide layers 276 include titanium and silicon and can be referred to as titanium silicide layers. The second metal layer may be different from the first metal layer 274. For example, when the source/drain feature(s) are of n-type, electronegativity of the second metal layer may be greater than electronegativity of the first metal layer 274. For example, when the source/drain feature(s) are of p-type, electronegativity of the second metal layer may be lower than electronegativity of the first metal layer 274. The electronegativity difference may result in improved dipole effect, thus reducing resistance between a metal fill layer (to be formed in the trenches 268) and the source/drain features 230 and/or 244. The metal constituents of the first metal layer 274 and the second metal layer may be chosen according to the conductivity type (e.g., p-type or n-type) of the source/drain feature(s) 244 or the source/drain feature(s) 230. In some embodiments, the metal constituents of the first metal layer 274 and the second metal layer are chosen according to the conductivity type of the source/drain feature(s) 244. For example, the source/drain feature(s) 244 are n-type source/drain feature(s), the metal constituent of the second metal layer includes Ti, Zr, Hf, Sc, Y, Yb, La, Er, Dy, Ce, or a combination thereof, and electronegativity of the second metal layer may be greater than electronegativity of the first metal layer 274. In some embodiments, the first silicide layer 272 includes zirconium silicide and the second silicide layer 276 includes titanium silicide.

The silicide layers (e.g., the first silicide layer 272-2 and the second silicide layer 276-2) on the source/drain feature 244-2, the silicide layers (e.g., the first silicide layer 272-3 and the second silicide layer 276-3) on the source/drain feature 244-3, and the silicide layers (e.g., the first silicide layer 272T/272B and the second silicide layer 276T/276B) on the source/drain features 244-1 and 230-1 may be formed simultaneously or separately. In some embodiments, the source/drain features 244 are of a same type (e.g., n-type), and the source/drain features 230 are of an opposite type (e.g., p-type). In some embodiments, the first silicide layers 272 on the source/drain features 244-2, 244-1 and 230-1, and 244-3 include a same metal (e.g., selected from Ti, Zr, Hf, Sc, Y, Yb, La, Er, Dy, Ce, or a combination thereof), and the second silicide layers 276 on the source/drain features 244-2, 244-1 and 230-1, and 244-3 include a same metal (e.g., selected from Ti, Zr, Hf, Sc, Y, Yb, La, Er, Dy, Ce, or a combination thereof). In some embodiments, the silicide layers on the source/drain feature 244-2, the silicide layers on the source/drain feature 244-3, and the silicide layers on the source/drain features 244-1 and 230-1 include different metals (e.g., independently selected from Ti, Zr, Hf, Sc, Y, Yb, La, Er, Dy, Ce, or a combination thereof). In some other embodiments, the source/drain feature 244-2 is of an opposite type from the source/drain features 244-1 and 244-3. For example, the source/drain feature 244-2 is of p-type, the silicide layers thereon include metal constituents selected from Al, W, Mo, Co, Ru, Re, Rh, Ir, Pt, Ni, Pd, Nb, V, or a combination thereof. For example, the source/drain features 244-1 and 244-3 are of n-type, the silicide layers thereon include metal constituents selected from Ti, Zr, H f, Sc, Y, Yb, La, Er, Dy, Ce, or a combination thereof.

In some embodiments, operations at block 110 further include performing a nitridation process to the second silicide layers 276. The nitridation process is optional. The nitridation process includes purging nitrogen over the second silicide layers 276, thereby converting a surface portion of the second silicide layers 276 into nitrogen-containing layers 276′. The nitrogen-containing layers 276′ thus further include nitrogen compared to the second silicide layers 276. In some embodiments, the nitrogen-containing layers 276′ include titanium, silicon, and nitrogen. In some embodiments, the nitrogen-containing layers 276′ include titanium silicon nitride (TiSiN). The nitrogen-containing layers 276′ may have a thickness of less than about 3 nm and may protect the second silicide layers 276 therebelow from oxidation in the following processes. In some embodiments, forming the second silicide layers 276 and performing the nitridation process are in-situ at the second temperature. For the purpose of simplifying, the nitrogen-containing layers 276′ are not depicted in the following figures.

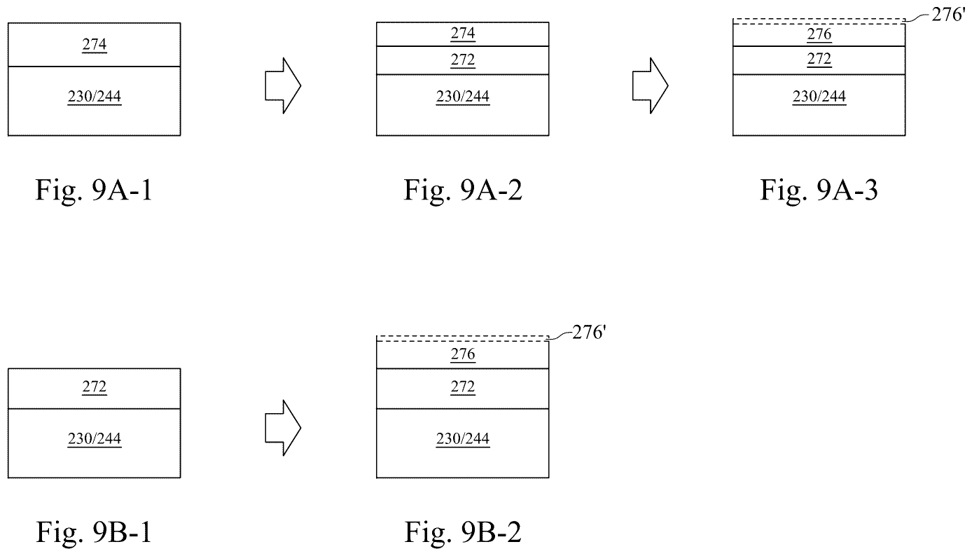

In some embodiments, performing the first thermal process and forming the second silicide layers 276 are combined in a same process. FIGS. 9A-1 to 9A-3 illustrate fragmentary schematic cross-sectional views of a surface of the source/drain feature 230 or 244 during the operations at blocks 108 and 110. In some embodiments, depositing the first metal layer 274 (shown in FIG. 9A-1) is at a temperature lower than about 60 degree C. (e.g., room temperature). In some embodiments, performing the first thermal process (shown in FIG. 9A-2) and forming the second silicide layers 276 (shown in FIG. 9A-3) are simultaneous at a temperature greater than about 400 degree C., for example, at about 400 to about 500 degree C. If the temperature is too low (e.g., lower than about 400 degree C., forming the first silicide layer 272 and the second silicide layer 276 may be too slow. If the temperature is too high (e.g., greater than about 500 degree C.), existing features (e.g., the source/drain features 230 and 244) of the structure 200 may be damaged. Performing the first thermal process and performing the operations at block 110 maybe in-situ (e.g., in a same chamber). In some embodiments, depositing the second metal layer includes applying a precursor, such as a metal halide (e.g, TiCl₄), to the structure 200. The precursor may remove the remaining portion of the first metal layer 274 (as in FIG. 9A-2) and form the second silicide layer 276. The metal halide may include the metal of the second silicide layer 276. The nitrogen-containing layer 276′ may be optionally formed. In the embodiments represented by FIGS. 9A-1 to 9A-3, total thermal energy consumed may be reduced, as depositing the first metal layer 274 is at a relatively low temperature, and performing the first thermal process and the operations at block 110 are in-situ and/or simultaneous.

In some other embodiments, performing the first thermal process at block 108 is before the operations at block 110. FIGS. 9B-1 to 9B-2 illustrate fragmentary schematic cross-sectional views of a surface of the source/drain feature 230 or 244 during the operations at blocks 108 and 110. In such embodiments, depositing the first metal layer 274 and performing the first thermal process at block 108 (shown in FIG. 9B-1) may be performed simultaneously in a same chamber at a temperature greater than about 400 degree C., for example, at about 400 to about 500 degree C. In such embodiments, depositing the first metal layer 274 and performing the first thermal process may collectively be referred to as performing a high temperature PVD process. After performing the high temperature PVD process, any suitable process may be performed to remove the remaining portions of the first metal layer 274. For example, by purging a halide gas and/or applying the precursor described above. Forming the second silicide layer 276 (shown in FIG. 9B-2) may be in a same or a different chamber from the operations at block 108. The nitrogen-containing layer 276′ may be optionally formed.

Various parameters of the operations (e.g., the PVD process, the CVD process) at blocks 108 and 110 may be tuned to achieve designed thicknesses (to be described below) of the first silicide layers 272 and the second silicide layers 276, such as composition of the gases, the temperatures, the time durations, pressures, gas flow rates, source power, bias power, bias voltage, other suitable parameters, or combinations thereof.

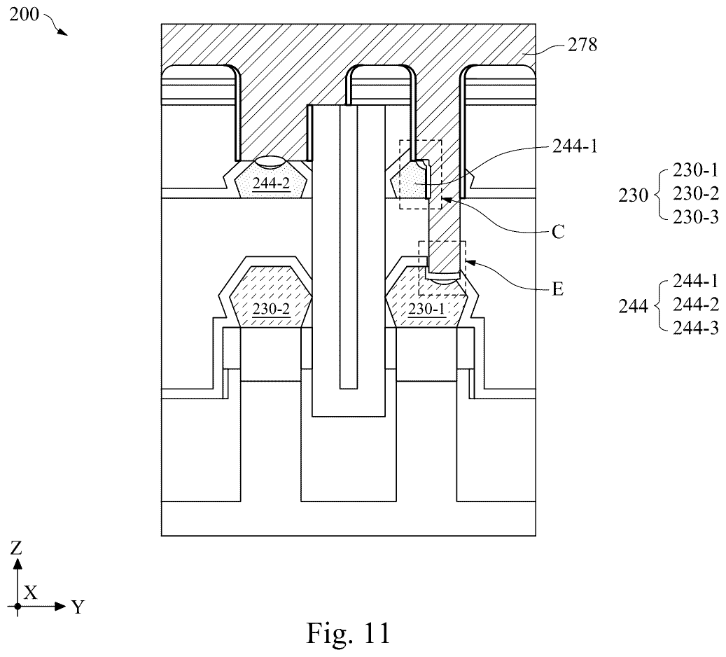

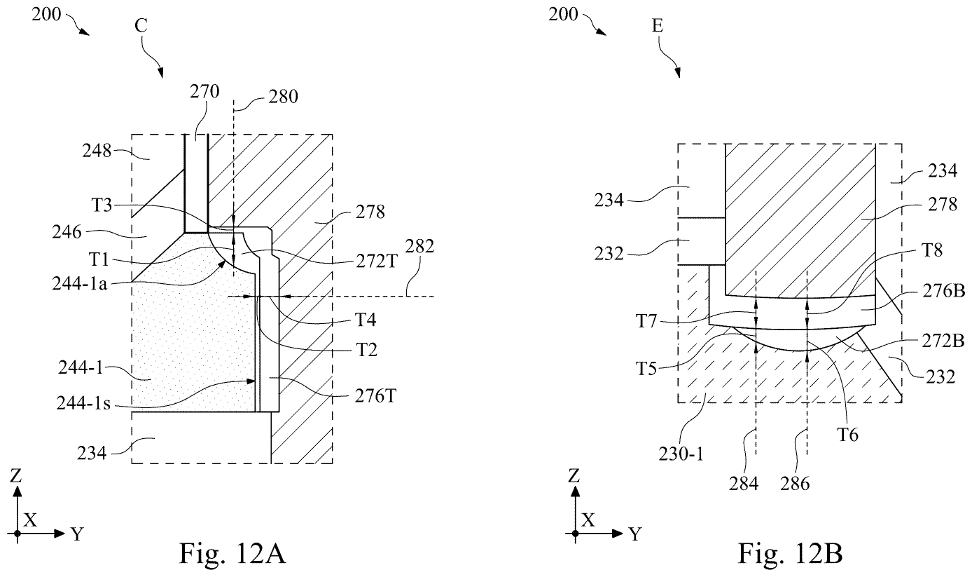

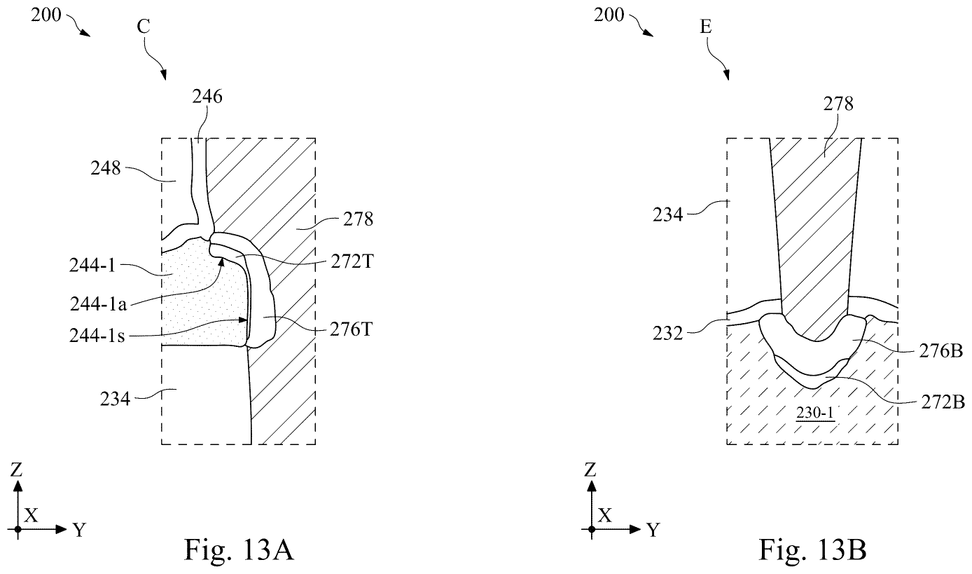

Referring to FIGS. 1 and 10-13B, method 100 includes a block 112 where a metal fill layer 278 is filled in the trench 268. FIGS. 12A and 13A illustrate enlarged views of a portion C of the structure 200 as in FIG. 11 according to various embodiments. FIGS. 12B and 13B illustrate enlarged views of a portion E of the structure 200 as in FIG. 11 according to some embodiments.

The metal fill layer 278 may be formed over the second silicide layers 276. The metal fill layer 278 may include tungsten (W), cobalt (Co), molybdenum (Mo), ruthenium (Ru), copper (Cu), nickel (Ni), titanium (Ti), tantalum (Ta), titanium nitride (TiN), tantalum nitride (TaN), or other metals, and may be formed by CVD, PVD, ALD, plating, or other suitable processes. In some embodiments, the metal fill layer 278 includes W. In some embodiments, the metal fill layer 278 includes a plurality of layers. In some embodiments, the structure 200 further includes metal liner(s) between the metal fill layer 278 and surrounding dielectric materials. In some embodiments, the metal liner(s) is between metal fill layer 278 and second silicide layers 276.

Referring to FIG. 12A, the first silicide layer 272T on a sidewall 244-1s and a top surface 244-1a of the source/drain feature 244-1 have different thicknesses, and the second silicide layer 276T over the sidewall 244-1s and the top surface 244-1a have different thicknesses. The top surface 244-1a of the source/drain feature 244-1 may be curved and may decline toward the sidewall 244-1s as depicted. In some embodiments, the first silicide layer 272T has a thickness Ti (or a vertical thickness T1) and a thickness T2 (or a horizontal thickness T2) along a vertical line 280 and along a horizontal line 282, respectively. The vertical line 280 intersects the top surface 244-1a and the horizontal line 282 intersects the sidewall 244-1s. In some embodiments, T2 is less than about 3 nm, such as about 1 nm. T1 may be greater than T2. A ratio of T1 to T2 is about 2 to about 10. This may result from the deposition of the first metal layer 274 at block 108, in which the first metal layer 274 may be deposited more over the top surface 244-1a than over the sidewall 244-1s. The relatively thin T2 leaves more space for the metal fill layer 278 in the trench 268-1 (e.g., in the region between the second silicide layer 276T and the opposing sidewall of the trench 268-1), mitigating necking profile therein. Thus, filling the trench 268-1 with the metal fill layer 278 may be improved. In some embodiments, no air gap is formed in the metal fill layer 278. In some embodiments, the second silicide layer 276T has a thickness T3 (or a vertical thickness T3) and a thickness T4 (or a horizontal thickness T4) along the vertical line 280 and along the horizontal line 282, respectively. T3 may be less than T4. A ratio of T3 to T4 may be about 2:3 to about 1:10. This may result from the different thicknesses (e.g., T1 and T2) of the first silicide layer 272T. In an example, when forming the second silicide layer 276T, constituents (e.g., Si) of the source/drain feature 244-1 diffused through a thinner portion (e.g., the portion having the thickness T2) of the first silicide layer 272T are in a greater amount than constituents of the source/drain feature 244-1 diffused through a thicker portion (e.g., the portion having the thickness T1) of the first silicide layer 272T. In some embodiments, a ratio of T1 to T3 is about 3:2 to about 20:1. If the ratio is too small (e.g., less than about 3:2), T1 may be too small, the dipole effect at the silicide layers 272T and 276T may be too small; or T3 may be too large, resistance of the source/drain contact may be too large. If the ratio is too large (e.g., greater than about 20:1), T3 may be too small, the dipole effect may be too small; or T1 may be too large, resistance of the source/drain contact may be too large. In some embodiments, a ratio of T2 to T4 may be about 1:2 to about 1:20. If the ratio is too small (e.g., less than about 1:20), T2 may be too small, the dipole effect may be too small; or T4 may be too large, the second silicide layer 276T may take up too much space, which may cause filling failures (e.g., void formation) of the metal fill layer 278 in the trench 268-1. If the ratio is too large (e.g., greater than about 1:2), T2 may be too large, which may cause filling failures of the metal fill layer 278 in the trench 268-1; or T4 may be too small, the dipole effect may be too small.

Referring to FIG. 12B, for similar reasons, the first silicide layer 272B may have various thicknesses at different positions along the Y-direction. For example, along a vertical line 284 and a vertical line 286, the first silicide layer 272B has a thickness T5 (or a vertical thickness T5) and a thickness T6 (or a vertical thickness T6), respectively. The vertical line 286 is closer to a vertical center line of the first silicide layer 272B than the vertical line 284. Thus, the first silicide layer 272B may be thicker in a middle portion than in side portions. In some embodiments, along the vertical line 284 and the vertical line 286, the second silicide layer 276B has a thickness T7 (or a vertical thickness T7) and a thickness T8 (or a vertical thickness T8), respectively. In some embodiments, a ratio of T5 to T7 is about 1:2 to about 1:20. If the ratio is too small (e.g., less than about 1:20), T5 may be too small, the dipole effect at the silicide layers 272T and 276T may be too small; or T7 may be too large, the resistance of the source/drain contact may be too large. If the ratio is too large (e.g., greater than about 1:2), T5 may be too large, the resistance of the source/drain contact may be too large; or T7 may be too small, the dipole effect may be too small. A ratio of T6 to T8 may be about 1:1.5 to about 1:5. If the ratio is too small (e.g., less than about 1:5), T8 may be too large, resistance of the source/drain contact may be too large, and the time and cost associated therewith may be too much; or T6 may be too small, the dipole effect may be too small. If the ratio is too large (e.g., greater than about 1:1.5), T6 may be too large, resistance of the source/drain contact may be too large, and the time and cost associated therewith may be too much; or T8 may be too small, the dipole effect may be too small.

FIGS. 13A and 13B illustrate alternative enlarged views of the portions C and E, respectively. Referring to FIG. 13A, the top surface 244-1a and the sidewall 244-1s are connected by a rounded corner. In the depicted embodiment, thicknesses of the first silicide layer 272T gradually decrease from top to bottom. A thickness of a layer is measured along a direction perpendicular to a surface (e.g., the top surface 244-1a, the sidewall 244-1s, the rounded corner) depending on where the thickness is. In the depicted embodiment, thicknesses of the second silicide layer 276T gradually increase from top to bottom. In some embodiments, a sum of a thickness of the first silicide layer 272T and a thickness of the second silicide layer 276T from top to bottom is about the same. For example, the sum at a point of the top surface 244-1a is about the same as the sum at a point of the sidewall 244-1s. Referring to FIG. 13B, the first silicide layer 272B and the second silicide layer 276B may each have a shape of an arc. In some embodiments, a thickness of the second silicide layer 276B is greater than a thickness of the first silicide layer 272B.

It is noted that the thickness of the nitrogen-containing layers 276′ (if any) is included in the thickness of the second silicide layers 276 described above. The thicknesses of the first silicide layers 272 and the second silicide layers 276 disclosed above may improve dipole effect at interfaces of the first silicide layers 272, the second silicide layers 276, and the source/drain feature(s) 244 and/or 230, thus reducing the resistance of source/drain contacts (to be described below).

Referring to FIGS. 1 and 14-15, method 100 includes a block 114 where planarization operation, such as a CMP process, is performed to remove excessive materials. The planarization process may be performed until reaching and exposing an ESL, such as the ESL 262-2, which functions as a planarization stop layer. Remainders of the metal fill layer 278, the first silicide layers 272, and the second silicide layers 276 form source/drain contacts 288-1, 288-2, and 288-3 as depicted.

The structure 200 may undergo further processes to form various features and regions known in the art. For example, subsequent processing may form additional interlayer dielectric (ILD) layer(s), contacts/vias/lines and multilayers interconnect features (e.g., metal layers and interlayer dielectrics) over the substrate 202, configured to connect the various features to form a functional circuit that may include one or more devices including the semiconductor device 200. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure.

Although FIGS. 2-15 illustrate stacked transistor structures having GAA transistors, other examples of semiconductor devices (e.g., multigate devices, stacked transistor structures having any combination of transistors, such as planar, FinFET, nanosheet, and nanowire transistors) may benefit from aspects of the present disclosure.

Referring to FIGS. 16 and 2-4, method 300 includes a block 302 where a structure 400 is provided or formed. Operations at block 302 are similar to the operations at block 102 of method 100 as described above. At this stage, the structure 400 is similar to the structure 200 at block 102.

Referring to FIGS. 16-18, method 300 includes a block 304 where the trenches 268 are formed to expose the top source/drain features 244 and the bottom source/drain features 230, and a block 306 where the dielectric liner 270 is formed. Operations at blocks 304 and 306 are similar to those at block 104 and 106, respectively.

Still referring to FIGS. 16-18, method 300 includes a block 308 where a third silicide layer 290 is formed on the exposed surfaces of the source/drain features 230 and 244. Before forming the third silicide layer 290, a cleaning process similar to that at block 108 may be performed.

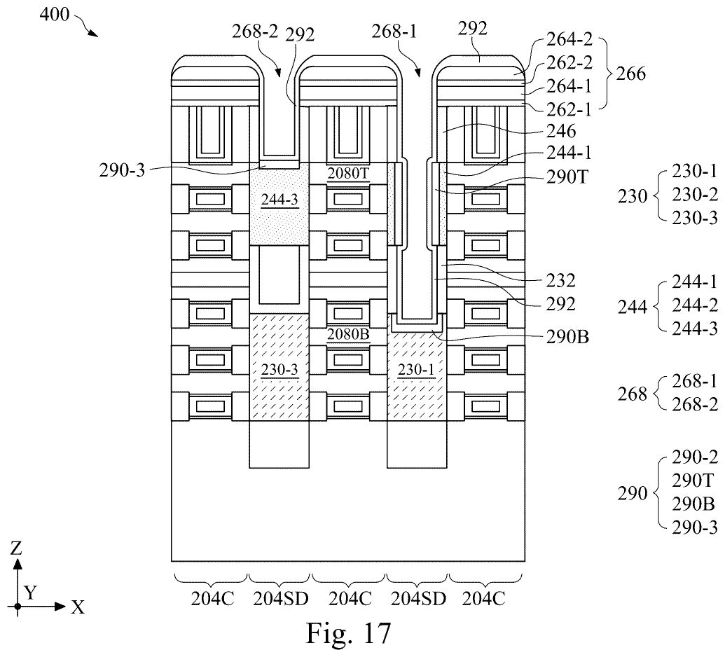

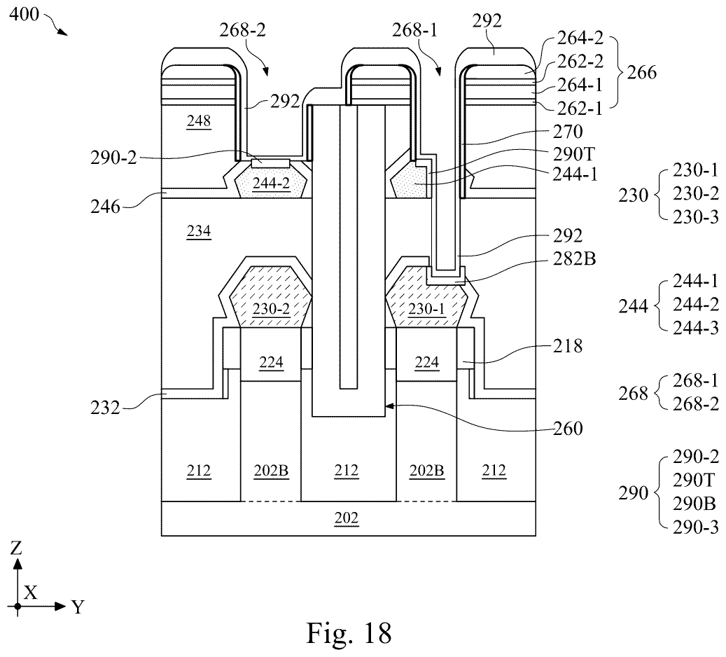

In FIGS. 17 and 18, the third silicide layers 290 may include third silicide layers 290-3, 290-2, 290T, and 290B disposed on the source/drain features 244-3, 244-2, 244-1, and 230-1, respectively. The third silicide layers 290-3, 290-2, 290T, and 290B may be collectively or individually referred to as the third silicide layer(s) 290 as the context requires. Forming the third silicide layers 290 may include depositing a third metal layer 292 over the structure 400 (including exposed surfaces of the source/drain features 230 and 244 in the trenches 268) at a third temperature of about 400 degree C. to about 450 degree C. to cause constituents of the source/drains features 230 and 244 to react with metal constituents in the third metal layer 292.

Depositing the third metal layer 292 over the exposed surfaces of the source/drain features 230 and 244 in the trenches 268 may be by a suitable deposition process, such as a CVD process, a plasma enhanced CVD process. In some embodiments, depositing the third metal layer 292 includes a CVD process. The third metal layer 292 may also be deposited on sidewalls of the dielectric materials (e.g., the CESL 246 and 232, the dielectric liner 270, the ILD layer 234) in the trenches 268 and over the gate isolation structure 260 and the patterned mask layer 266. In some embodiments, the third metal layer 292 on the sidewalls of the dielectric materials are thicker than the third metal layer 292 over the exposed surfaces of the source/drain features 230 and 244.

In some embodiments, at the third temperature, portions of the source/drain features 244-3, 244-2, 244-1, and 230-1 are consumed and converted into the third silicide layers 290-3, 290-2, 290T, and 290B, respectively. The third metal layer 292 may include any metal constituent suitable for promoting silicide formation, such as zirconium, nickel, platinum, palladium, vanadium, titanium, cobalt, tantalum, ytterbium, other suitable metal, or a combination thereof. When the source/drain feature(s) are of n-type, the metal constituent may include Ti, Zr, Hf, Sc, Y, Yb, La, Er, Dy, Ce, or a combination thereof. When the source/drain feature(s) are of p-type, the metal constituent may include Al, W, Mo, Co, Ru, Re, Rh, Ir, Pt, Ni, Pd, Nb, V, or a combination thereof. The metal constituent of the third metal layer 292 may be chosen according to the conductivity type (e.g., p-type or n-type) of the source/drain feature(s) 244 or the source/drain feature(s) 230. In some embodiments, the metal constituent is chosen according to the conductivity type of the source/drain feature(s) 244. The third silicide layers 290 thus include a metal constituent and a constituent of the source/drain features 244-3, 244-2, 244-1, and 230-1 (for example, silicon and/or germanium). In some embodiments, the third metal layer 292 is a zirconium-containing layer, and the third silicide layers 290 include zirconium and silicon and can be referred to as zirconium silicide layers. In some embodiments, after forming the third silicide layer 290, un-reacted metal, such as remaining portions of the third metal layer 292, remains in the trenches 268.

Referring to FIGS. 16 and 19-20, method 300 includes a block 310 where a soak process is performed. The soak process removes un-reacted metal, such as the remaining portions of the third metal layer 292.

In some embodiments, the soak process includes purging a halide gas over the structure 400 at a temperature of about 350 degree C. to about 450 degree C. The halide gas may react with the remaining portions of the third metal layer 292. The halide gas may include hydrochloric acid (HCl), hydrogen fluoride (HF), chlorine (Cl₂), boron trichloride (BCl₃), or a combination thereof. In some embodiments, the halide gas includes a metal halide, such as the precursor described above for block 110. In such embodiments, a fourth silicide layer containing the metal in the metal halide may be formed over the third silicide layer, similarly to forming the second silicide layer 276 over the first silicide layer 272. Byproduct residues including halide from the soak process may remain on the surfaces (e.g., the sidewalls) of the dielectric materials in the trenches 268.

In some embodiments, method 300 includes a plurality of cycles of depositing the third metal layer 292 and performing the soak process. This may improve control of the formation of the third silicide layer 290 and removal of excess third metal layer 292, while protecting the third silicide layer 290 from the halide gas. In some embodiments, depositing the third metal layer 292 and performing the soak process are simultaneous. In other words, the halide gas is flowed over the structure 400 simultaneously as the deposition of the third metal layer 292 at the third temperature. Flowing the halide gas simultaneously may mitigate deposition of the third metal layer 292 on the dielectric materials in the trenches 268.

Still referring to FIGS. 16 and 19-20, method 300 includes a block 312 where a post treatment is performed to remove the byproduct residues including halide (e.g., Cl, F) of the halide gas. Removing the byproduct residues may reduce resistance of the source/drain contact to be formed.

In some embodiments, performing the post treatment includes performing a plasma process. In some embodiments, the plasma process uses an inert gas, such as argon (Ar) and helium (He) to generate plasma for removing the byproduct residues. In some embodiments, the plasma process uses a reactive gas, such as hydrogen (H₂), ammonia (NH₃), hydrazine (N₂H₄), or a combination thereof. In such embodiments, the reactive gas may react with the byproduct residues and/or may generate plasma to remove the byproduct residues. In the embodiments where the reactive gas includes a nitrogen-containing gas (e.g., NH₃, N₂H₄), the nitrogen-containing gas may react with a surface portion of the third silicide layer 290 to form a nitrogen-containing layer similar to the forming of the nitrogen-containing layer 276′ as described above at block 110. In the embodiments where the reactive gas does not include a nitrogen-containing gas (e.g., NH₃, N₂H₄), a nitridation process similar as described above may be performed to the structure 400. In some embodiments, the plasma process uses both an inert gas and a reactive gas. The post treatment may be at a temperature of about 350 degree C. to about 450 degree C.

The operations at blocks 308, 310, and 312 may be in-situ. In some embodiments, depositing the third metal layer 292, performing the soak process, and performing the post treatment are in a same chamber, thus reducing time and cost associated therewith. By performing the soak process and the post treatment, a majority (e.g., greater than about 95%) of the remaining portions of the third metal layer 292 is removed from the sidewalls of the dielectric materials in the trenches 268. Thus, more space is left for a metal fill layer to be formed in the trenches 268, source/drain contacts to be formed may have improved integration in a planarization process (e.g., a CMP process), resistance of the source/drain contacts may be reduced, and liability of the structure 400 may be improved. Performing the soak process and the post treatment are especially beneficial when the third metal layer 292 on the sidewalls of the dielectric materials are thicker than the third metal layer 292 over the exposed surfaces of the source/drain features 230 and 244 at block 308.

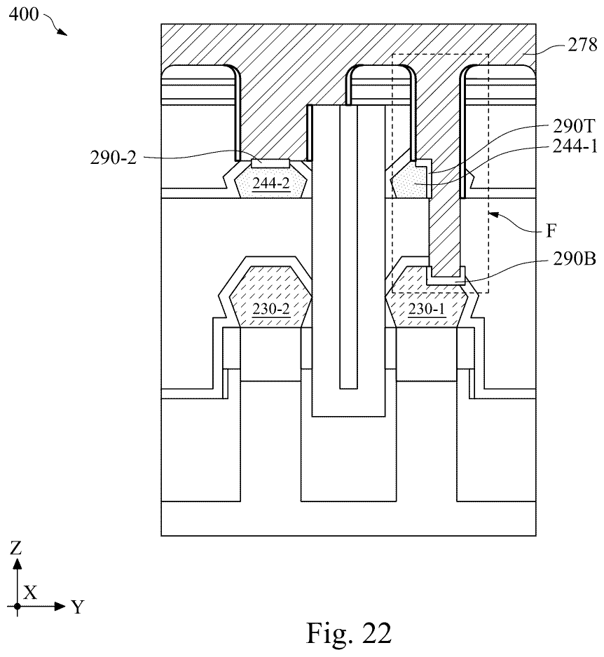

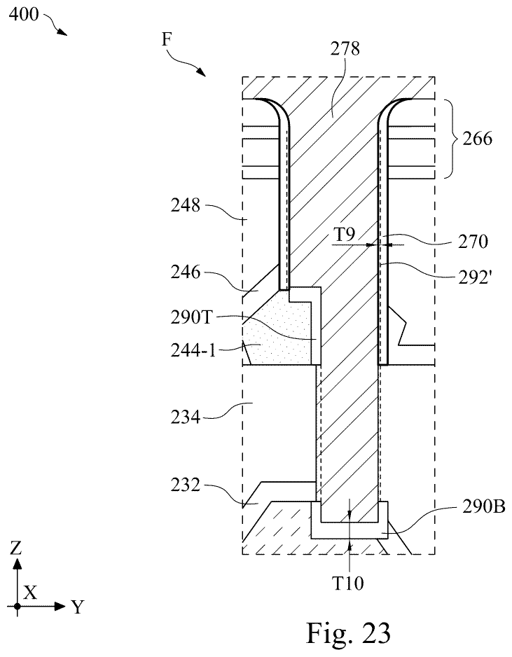

Referring to FIGS. 16 and 21-23, method 300 includes a block 314 where a metal fill layer 278 is filled in the trench 268 similarly as described above at block 112. FIG. 23 illustrates an enlarged view of a portion F of the structure 400 as in FIG. 22 according to various embodiments.

Referring to FIG. 23, a majority (e.g., greater than about 95%) of the third metal layer 292 in the trenches 268 is removed in the soak process. In some embodiments, a thickness T9 of the remaining portion 292′ of third metal layer 292 on the sidewalls of the dielectric materials (e.g., the dielectric liner 270, the CESL 232, and the ILD layer 234) is less than about 1 nm, such as about 0.5 nm. In the depicted embodiment, the third silicide layer 290B has a vertical thickness T10 of about 5 nm to about 7 nm. In some embodiments, a ratio of T10 to T9 is about 10 to about 100. If the ratio is too small (e.g., less than about 10), T9 may be too large, the remaining portion 292′ is too much, the third metal layer 292 is not sufficiently removed, which may impact reliability and integrity of the source/drain contact. If the ratio is too large (e.g., greater than about 100), T10 may be too large, resistance of the source/drain contact may be too large, and the time and cost associated therewith may be too much.

Referring to FIGS. 16 and 24-25, method 300 includes a block 316 where a planarization process is performed similarly as described above at block 114. Differences from the structure 200 at block 114 include the follows. Remainders of the metal fill layer 278, the third silicide layers 290, and the remaining portion 292′ (if any, as shown in FIG. 23) of third metal layer 292 form source/drain contacts 288-1′, 288-2′, and 288-3′ as depicted. The structure 400 may undergo further processes similar as described above to the structure 200.

Although not intended to be limiting, one or more embodiments of the present disclosure provide many benefits to a semiconductor structure. For example, by forming silicide layers having different compositions and the disclosed dimensions, dipole effect may be increased to reduce the resistance of the source/drain contact, necking profile in the trench may be mitigated, and thermal energy consumption in forming the silicide layers may be reduced. For example, by performing a soak process and a post treatment after forming the silicide layer, metal residues on sidewalls of the trench may be removed, metal filling in the trench may be improved, resistance of the source/drain contact may be reduced, integration of the structure in a following planarization process (e.g., a CMP process) may be improved, and reliability of the device may be improved. Thus, the overall performance of the semiconductor device may be improved.

In one exemplary aspect, the present disclosure is directed to a method. The method includes providing a structure. The structure includes a bottom source/drain feature, a bottom interlayer dielectric (ILD) layer disposed over the bottom source/drain feature, a top source/drain feature disposed over the bottom ILD layer and the bottom source/drain feature, and a top ILD layer disposed over the top source/drain feature. The method further includes forming a trench extending in the top ILD layer and the bottom ILD layer. The trench exposes a top surface and a sidewall of the top source/drain feature and a top surface of the bottom source/drain feature. The method further includes forming first silicide layers on the top surface and the sidewall of the top source/drain feature and the top surface of the bottom source/drain feature, forming second silicide layers on the first silicide layers, and forming a metal fill layer in the trench. The first silicide layers and the second silicide layers have different compositions.

In some embodiments, the first silicide layers include zirconium silicon, and the second silicide layers include titanium silicon. In some embodiments, forming the first silicide layers includes performing a physical vapor deposition process and forming the second silicide layers includes performing a chemical vapor deposition process. In some embodiments, performing the physical vapor deposition process is at a first temperature, and performing the chemical vapor deposition process is at a second temperature greater than the first temperature. In some embodiments, forming the second silicide layers includes depositing a metal layer over the first silicide layers to react with silicon diffused through the first silicide layers. In some embodiments, forming the first silicide layers and forming the second silicide layers include depositing a first metal on the top surface and the sidewall of the top source/drain feature and the top surface of the bottom source/drain feature at a first temperature, performing a thermal process to the structure at a second temperature greater than the first temperature, thereby forming the first silicide layers, and depositing a second metal on the first silicide layers at the second temperature, thereby forming the second silicide layers. Performing the thermal process and depositing the second metal are in a same chamber. In some embodiments, the second temperature is of about 400 degree C. to about 500 degree C. In some embodiments, the method further includes purging nitrogen over the second silicide layers.

In another exemplary aspect, the present disclosure is directed to a method. The method includes providing a structure including a source/drain feature and an interlayer dielectric (ILD) layer disposed over the source/drain feature, forming a contact trench in the ILD layer to expose a top surface and a sidewall of the source/drain feature, forming a first silicide layer including a first horizontal portion on the top surface of the source/drain feature and a first vertical portion on the sidewall of the source/drain feature, forming a second silicide layer on the first silicide layer, and forming a metal fill layer in the contact trench. The second silicide layer includes a second horizontal portion on the first horizontal portion and a second vertical portion along the first vertical portion. The first horizontal portion has a first thickness, the first vertical portion has a second thickness, the second horizontal portion has a third thickness, and the second vertical portion has a fourth thickness. The first thickness is greater than the second thickness, and the third thickness is less than the fourth thickness.

In some embodiments, forming the first silicide layer includes performing a physical vapor deposition process. In some embodiments, forming the second silicide layer includes performing a chemical vapor deposition process. In some embodiments, a ratio of the first thickness to the third thickness is in a range of about 3:2 to about 20:1. In some embodiments, a ratio of the second thickness to the fourth thickness is in a range of about 1:2 to about 1:20. In some embodiments, a ratio of the first thickness to the second thickness is about 2 to about 10. In some embodiments, forming the first silicide layer includes depositing a first metal on the source/drain feature, forming the second silicide layer includes depositing a second metal on the first silicide layer, and the second metal is different from the first metal. In some embodiments, electronegativity of the second metal is greater than electronegativity of the first metal.

In yet another exemplary aspect, the present disclosure is directed to a semiconductor structure. The semiconductor structure includes a bottom transistor and a top transistor disposed above the bottom transistor. The bottom transistor includes a bottom source/drain feature and the top transistor includes a top source/drain feature. The semiconductor structure further includes a first silicide layer disposed on the top source/drain feature and the bottom source/drain feature, a second silicide layer disposed on the first silicide layer, and a metal fill layer disposed on the second silicide layer. The first silicide layer and the second silicide layer have different compositions, the first silicide layer includes a first horizontal portion on a top surface of the top source/drain feature and a first vertical portion along a sidewall of the top source/drain feature, and the first horizontal portion has a first thickness, and the first vertical portion has a second thickness less than the first thickness.

In some embodiments, the first silicide layer includes a first metal having a first electronegativity, and the second silicide layer includes a second metal having a second electronegativity greater than the first electronegativity. In some embodiments, the second silicide layer includes a second horizontal portion on the first horizontal portion and a second vertical portion along the first vertical portion, the second horizontal portion has a third thickness, and the second vertical portion has a fourth thickness greater than the third thickness. In some embodiments, a first sum of the first thickness and the third thickness is about the same as a second sum of the second thickness and the fourth thickness.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
providing a structure comprising:
a bottom source/drain feature,
a bottom interlayer dielectric (ILD) layer disposed over the bottom source/drain feature,
a top source/drain feature disposed over the bottom ILD layer and the bottom source/drain feature, and
a top ILD layer disposed over the top source/drain feature;
forming a trench extending in the top ILD layer and the bottom ILD layer, wherein the trench exposes a top surface and a sidewall of the top source/drain feature and a top surface of the bottom source/drain feature;
forming first silicide layers on the top surface and the sidewall of the top source/drain feature and the top surface of the bottom source/drain feature;
forming second silicide layers on the first silicide layers, wherein the first silicide layers and the second silicide layers have different compositions; and
forming a metal fill layer in the trench.

2. The method of claim 1, wherein the first silicide layers comprise zirconium silicon, and the second silicide layers comprise titanium silicon.

3. The method of claim 1, wherein forming the first silicide layers comprises performing a physical vapor deposition process and forming the second silicide layers comprises performing a chemical vapor deposition process.

4. The method of claim 3, wherein performing the physical vapor deposition process is at a first temperature, and performing the chemical vapor deposition process is at a second temperature greater than the first temperature.

5. The method of claim 1, wherein forming the second silicide layers comprises depositing a metal layer over the first silicide layers to react with silicon diffused through the first silicide layers.

6. The method of claim 1, wherein forming the first silicide layers and forming the second silicide layers comprise:
depositing a first metal on the top surface and the sidewall of the top source/drain feature and the top surface of the bottom source/drain feature at a first temperature;
performing a thermal process to the structure at a second temperature greater than the first temperature, thereby forming the first silicide layers; and
depositing a second metal on the first silicide layers at the second temperature, thereby forming the second silicide layers,
wherein performing the thermal process and depositing the second metal are in a same chamber.

7. The method of claim 6, wherein the second temperature is of about 400 degree C. to about 500 degree C.

8. The method of claim 1, further comprising purging nitrogen over the second silicide layers.

9. A method comprising:
providing a structure comprising a source/drain feature and an interlayer dielectric (ILD) layer disposed over the source/drain feature;
forming a contact trench in the ILD layer to expose a top surface and a sidewall of the source/drain feature;
forming a first silicide layer comprising a first horizontal portion on the top surface of the source/drain feature and a first vertical portion on the sidewall of the source/drain feature;
forming a second silicide layer on the first silicide layer, wherein the second silicide layer comprises a second horizontal portion on the first horizontal portion and a second vertical portion along the first vertical portion; and
forming a metal fill layer in the contact trench,
wherein the first horizontal portion has a first thickness, the first vertical portion has a second thickness, the second horizontal portion has a third thickness, and the second vertical portion has a fourth thickness,
wherein the first thickness is greater than the second thickness, and the third thickness is less than the fourth thickness.

10. The method of claim 9, wherein forming the first silicide layer comprises performing a physical vapor deposition process.

11. The method of claim 9, wherein forming the second silicide layer comprises performing a chemical vapor deposition process.

12. The method of claim 9, wherein a ratio of the first thickness to the third thickness is in a range of about 3:2 to about 20:1.

13. The method of claim 9, wherein a ratio of the second thickness to the fourth thickness is in a range of about 1:2 to about 1:20.

14. The method of claim 9, wherein a ratio of the first thickness to the second thickness is about 2 to about 10.

15. The method of claim 9, wherein forming the first silicide layer comprises depositing a first metal on the source/drain feature,
wherein forming the second silicide layer comprises depositing a second metal on the first silicide layer, and
wherein the second metal is different from the first metal.

16. The method of claim 15, wherein electronegativity of the second metal is greater than electronegativity of the first metal.

17. A semiconductor structure, comprising:
a bottom transistor and a top transistor disposed above the bottom transistor, wherein the bottom transistor comprises a bottom source/drain feature and the top transistor comprises a top source/drain feature;
a first silicide layer disposed on the top source/drain feature and the bottom source/drain feature;
a second silicide layer disposed on the first silicide layer; and
a metal fill layer disposed on the second silicide layer,
wherein the first silicide layer and the second silicide layer have different compositions,
wherein the first silicide layer comprises a first horizontal portion on a top surface of the top source/drain feature and a first vertical portion along a sidewall of the top source/drain feature, and
wherein the first horizontal portion has a first thickness, and the first vertical portion has a second thickness less than the first thickness.

18. The semiconductor structure of claim 17, wherein the first silicide layer comprises a first metal having a first electronegativity, and
wherein the second silicide layer comprises a second metal having a second electronegativity greater than the first electronegativity.

19. The semiconductor structure of claim 17, wherein the second silicide layer comprises a second horizontal portion on the first horizontal portion and a second vertical portion along the first vertical portion,
wherein the second horizontal portion has a third thickness, and the second vertical portion has a fourth thickness greater than the third thickness.

20. The semiconductor structure of claim 19, wherein a first sum of the first thickness and the third thickness is about the same as a second sum of the second thickness and the fourth thickness.
